(19) United States
(12) Patent Application Publication
(10) Pub. No.: US 2025/0244545 A1
(43) Pub. Date: Jul. 31, 2025

(54) OPTICAL CHIP FOR FIBER EDGE COUPLING AND/OR ACTIVE PHOTONICS INTEGRATION

(71) Applicant: Mellanox Technologies, Ltd., Yokneam (IL)

(72) Inventor: Ashkan SEYEDI, Los Gatos, CA (US)

(21) Appl. No.: 18/943,302

(22) Filed: Nov. 11, 2024

Related U.S. Application Data
(60) Provisional application No. 63/626,349, filed on Jan. 29, 2024.
(60) Provisional application No. 63/568,163, filed on Mar. 21, 2024.

(51) Int. Cl. G02B 6/42; G02B 6/43

(52) U.S. Cl. CPC G02B 6/4243; G02B 6/4214; G02B 6/4215; G02B 6/43

(57) ABSTRACT

An optical chip configured for coupling to optical fibers and methods of manufacturing the same are provided. The optical chip includes a plurality of optical structures embedded within an optical routing layer; a first support layer; and a second support layer, bonded onto the exposed surface of the first support layer. The first support layer has a first etched mirror and a first v-groove aligned with the first etched mirror formed in an exposed surface of the first support layer. The second support layer has a second etched mirror and a second v-groove aligned with the second etched mirror formed in an exposed surface of the second support layer. The first etched mirror and the second etched mirror are optically aligned with a first optical structure and a second optical structure of the plurality of optical structures, respectively.

### CROSS-REFERENCE TO RELATED APPLICATIONS

This application claims priority to U.S. Application No. 63/626,349, filed Jan. 29, 2024, and U.S. Application No. 63/568,163, filed Mar. 21, 2024, the contents of which are incorporated herein by reference in their entireties.

### BACKGROUND

Technologies for fiber-to-chip attachment remain limited, in part due to the mismatch in alignment precision required by optics (within 1 μm) and the placement precision of high-volume pick and place machines (within 1-3 μm). Moreover, because misalignment of optical components may be additive along an optical path, the precision required for attaching an optical fiber to a chip may be below 1 μm, if a complex optical path is used.

Historically, optical beams have been expanded using a lens/reflective optical surface that trades off X-Y plane tolerance for increased angular tolerance. These approaches often rely on vertical emission of light and thus require bulky mechanical ferrules and structures to provide fiber strain, rigidity, and alignment. While these technologies are scalable in two dimensions of fiber arrays, the physical characteristics of these components (including the connector footprint and height clearance), are limiting in certain applications. Accordingly, a need exists for additional fiber-to-chip attachment technologies that are scalable in a wide variety of applications.

### GENERAL DESCRIPTION

Various embodiments provide an optical chip configured for coupling to an array (e.g., one-or two-dimensional array) of optical fibers and methods for fabrication thereof. In various embodiments, the optical chip includes a two-dimensional array of grooves configured for receiving a two-dimensional array of optical fibers therein. Etched mirrors (which may be curved in one-or two-dimensions to focus a light beam into a single plane or a single point) in the optical chip direct light to and/or from the optical fibers to corresponding optical structures in the optical chip (e.g., grating couplers) that are configured to couple the light into or out of optical components of the optical chip.

The present disclosure describes interconnects (e.g., interconnect topologies) that are scalable and advantageous for networks that require a large number of all-to-all or point-to-point links between one or more node or send/receive pairs. In particular, silicon photonics interconnects or topologies are provided herein that may achieve at least moderate bandwidth between many nodes with physical, optical fiber connections. In some implementations, the one or more node or send/receive pairs are coupled with an optical fiber allowing a single wavelength to pass therebetween. In other implementations, multiple wavelengths or groups of wavelengths may be transmitted or received by nodes while simultaneously passing multiple wavelengths or groups of wavelengths to other nodes via optical fiber loops connecting three or more nodes. In some implementations, such interconnects as described herein do not rely on or include one or more of the following: wavelength synchronization between transmit and receive pairs, arbitration of the fiber(s), demultiplexers on the receiver side, and/or an optical crossbar. In some implementations, the optical interconnects may be sized to fit a face-plate form factor or as a mid-board optical connector. In some embodiments, the present disclosure provides optical interconnects for high bandwidth density applications like switches and GPUs.

A “node” as described herein may refer to a network switch to which a plurality of computer processing units (CPUs), graphical processing units (GPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

However, it is generally difficult to accurately align light signals on the SiP with an external device that receives the light. For instance, long range transmission of light signals is generally performed within optical fibers. When optical signals are generated or processed in a SiP device for transmission over optical fibers, the light needs to be coupled between the SiP device and the optical fibers. This coupling between the SiP device and the optical fibers is generally difficult because waveguides within the SiP device generally comprise a smaller diameter than the optical fibers. As such, a “world-to-chip” interface problem often arises in SiP technologies where coupling of light between Si wire waveguides and optical fibers, and vice versa, is generally inefficient.

Traditionally, for fiber-to-chip coupling, a fiber coupling technique using spot-size converters (SSCs) or grating couplers is employed. However, grating couplers for fiber-to-chip coupling typically provide a narrow bandwidth and/or an undesirable polarization sensitivity for certain optical applications. Furthermore, SSCs and grating couplers for fiber-to-chip coupling are generally attached to the chip through an adhesive bonding technique that results in a silicon communication chip with bundles of fibers attached thereto, resulting in increased complexity for handling and/or assembly of the chips onto other optical systems. Additionally, wafers for traditional SiP devices are generally diced (e.g., fully cut through) to create an edge for the wafer to expose waveguide facets and/or to facilitate butt attachment of the SiP device to an external device.

Fiber-to-chip attach technologies remain a challenge due to the accuracy of alignment required by optics (within 1 μm) and the accuracy capabilities of high-volume pick and place machines (within 1-3 μm). To ease this tolerance, optical beams are expanded by means of a lens/reflective optical surface that trades off X-Y plane tolerance for increased angular tolerance. These approaches often rely on vertical emission of light and thus require bulky mechanical ferrules and structures to provide fiber strain, rigidity, and alignment. While they can easily scale to two dimensions of fiber arrays, the connector footprint and height clearance remain a challenge.

An alternate solution for fiber attach is referred to as edge coupling, whereby the light exits the optical chip laterally rather than vertically. By using crystal planes of silicon that can be readily exposed using wet etch chemistry, a so-called v-groove is formed, creating an ideal cradle in which a single-mode fiber can be seated. Traditionally, such a technology has only scaled in one dimension (beachfront of the chip) due, at least in part, to challenges in stacking silicon layers on top of each other to enable multi-layer v-grooves. This disclosure proposes a solution using currently-available wafer-to-wafer (W2W) bonding methodologies.

The technique of the present disclosure uses the fine alignment of W2W bonding, which is on the order of tens of nanometers, and high-accuracy etch processes to enable accurate optical coupling into an optical fiber. The v-groove, as defined by a wet etch, for example, enables mechanical registration of the optical fiber to have high accuracy of alignment to an optical path for providing an optical beam from the optical fiber to an optical routing layer of the optical chip or for providing an optical beam from the optical routing layer to the optical fiber. This technique provides an optical chip that includes a V-groove array for coupling optical fibers to the optical chip. The V-grooves are formed in s handles or wafers that are bonded to the optical chip. Etched mirrors and optical structures, such as mirrors or grating couplers, optically couple the optical fibers to optical components of the routing layer of the optical chip. Multiple handles or wafers may be stacked on the optical chip to enable coupling of a two-dimensional array of optical fibers to the optical chip.

According to an aspect of the present disclosure, an optical chip is provided. In an example embodiment, the optical chip includes a plurality of optical structures embedded within an optical routing layer; a first support layer secured with respect to the optical routing layer, wherein the first support layer has a first etched mirror formed in an exposed surface of the first support layer and a first groove on an edge of the first support layer aligned with the first etched mirror.

In general, a respective support layer is substantially prism-shaped or cylindrically disc-shaped with two substantially parallel faces of the prism or disc that act as the surfaces of the support layer. The remaining perimeter or boundary of the prism or disc are one or more edges of the support layer. In the scenario where the support layer is a rectangular prism, the two substantially parallel faces that have larger respective surface areas than then the remaining four faces are the surfaces of the support layer. The remaining four faces each define an edge of the respective support layer. In certain embodiments, at least one edge of a support layer aligns and/or is co-planar with an edge of the optical chip.

The optical chip further includes a second support layer, bonded onto the exposed surface of the first support layer, wherein the second support layer has a second etched mirror formed in a surface thereof and a second groove on an edge of the second support layer aligned with the second etched mirror.

The first etched mirror and the second etched mirror are optically aligned with a first optical structure and a second optical structure of the plurality of optical structures, respectively.

Grooves such as V-grooves or other suitable grooves are etched into the support layer at predefined positions and configured to receive respective optical fibers therein. The support layer is also etched to form etched mirror cavities that are aligned with respective grooves. Mirror sidewall surfaces defined at least in part by respective etched mirror cavities may be coated with an appropriate reflecting layer on a bevel to form an etched mirror, which is configured to direct light between an optical structure and an optical fiber placed in the V-groove.

In various embodiments, the support layers are configured to provide mechanical rigidity to remove the bulk substrate and enable through-vias through the insulation layer to the metallization layers for dense metal interconnection. For example, in some embodiments, the optical routing layer is formed on an insulating layer and metallization layers may be formed on the optical routing layer. The first support layer may be bonded to a surface of a metallization layer. Electrical connections to the metallization layer may be provided by through-vias that are formed through the insulating layer and the optical routing layer, for example.

According to another aspect of the present disclosure, a method for fabricating an optical chip is provided. In an example embodiment, the method includes forming a dielectric region onto an exposed surface of an optical routing layer of the optical chip, wherein the optical routing layer has a plurality of optical structures embedded therein; securing a first support layer onto an exposed surface of the dielectric region; and etching at least a first etched mirror and a first groove into an exposed surface of the first support layer. The first etched mirror is positioned to redirect an optical path from a first optical structure of the plurality of optical structures into the first groove and the first groove extends to an edge of the first support layer. The method further includes bonding a second support layer onto the exposed surface of the first support layer; and etching at least a second etched mirror and a second groove into an exposed surface of the second support layer. The second etched mirror is positioned to redirect an optical path from a second optical structure of the plurality of optical structures and into the second groove and the second groove extends to an edge of the second support layer.

According to another aspect of the present disclosure, a method of redirecting light within an optical chip is provided. In an example embodiment, the optical chip includes a support layer overlaid onto a dielectric region that is overlaid onto an optical routing layer having at least one optical structure configured to turn in-plane light from within the optical routing layer along an optical path passing through the dielectric region and into the support layer. In an example embodiment, the method includes etching a cavity into an exposed surface of the support layer to have a mirrored surface that is aligned with the optical path and angled to redirect light traveling along the optical path to an in-plane optical path portion that is at least substantially parallel with the exposed surface of the support layer.

According to another aspect of the present disclosure, a method for forming an optical chip is provided. In an example embodiment, the method includes forming a dielectric region onto the top surface of an optical routing layer of the optical chip, wherein the optical routing layer has a plurality of mirrors embedded therein; securing a first support layer onto an exposed surface of the dielectric region; and etching at least a first etched mirror and a first groove into an exposed surface of the first support layer. The first etched mirror is positioned to redirect an optical path from a first mirror within the optical routing layer of the plurality of mirrors within the optical routing layer into the first groove and the first groove extends to an edge of the first support layer.

The first etched mirror is etched using grayscale lithography. The method further includes bonding a second support layer onto the exposed surface of the first support layer; and etching at least a second etched mirror and a second groove into an exposed surface of the second support layer. The second etched mirror is positioned to redirect an optical path from a second mirror within the optical routing layer of the plurality of mirrors within the optical routing layer into the second groove and the second groove extends to an edge of the second support layer. The second etched mirror is etched using grayscale lithography. In an example embodiment, at least one mirror of the plurality of mirrors within the optical routing layer is a Bragg reflector.

According to another aspect, a method is provided for enabling edge coupling of optical fibers to an optical chip. In an example embodiment, the method includes etching at least a first etched mirror and a first groove into an exposed surface of a first support layer, wherein the first etched mirror and the first groove define a first portion of a first optical path; bonding a second support layer onto the exposed surface of the first support layer; and etching at least a second etched mirror and a second groove into an exposed surface of the second support layer, wherein the second etched mirror and the second groove define a first portion of a second optical path. The second optical path and the first optical path do not intersect one another.

According to another aspect, an optical interconnect for coupling a plurality of optical fibers to an optical chip is provided. The optical interconnect includes two or more support layers bonded to one another. Each support layer of the two or more support layers includes at least one etched mirror and at least one groove configured to receive an optical fiber of the plurality of optical fibers therein. The at least one etched mirror is configured to at least partially define an optical path between the at least one groove and a corresponding optical structure embedded in an optical routing layer of the optical chip. At least one of the at least one etched mirror or the corresponding optical structure is configured to cause an optical beam that traversed the optical to have, within at least a portion of the groove, an optical mode diameter that matches a mode field diameter of the optical fiber.

According to another aspect an optical chip is provided. The optical chip may include a laser formed in a V-etched into the optical chip. An etched mirror and optical structure, such as a mirror or grating coupler, optically couple the laser to optical components of the routing layer of the optical chip. The laser is formed in the V-groove such that the optical chip fabrication may be completed and then the components of the laser may be deposited into the V-groove. For example, the optical chip may be fabricated in one foundry and the laser may then be formed in the V-groove at another foundry such that the etching tool at the first foundry is not contaminated with III-V semiconductor material. In an example embodiment, the optical chip includes a plurality of optical structures embedded within an optical routing layer; and a support layer secured with respect to the optical routing layer. The support layer has at least one etched mirror formed in an exposed surface of the support layer and at least one groove etched into the exposed surface of the support layer and aligned with the at least one etched mirror. The optical chip further includes a first electrode, an active region including gain material, and a second electrode disposed within the groove. The active region is disposed between the first electrode and the second electrode. Applying a voltage difference between the first electrode and the second electrode causes the gain material to lase toward the at least one etched mirror. The at least one etched mirror is aligned with a respective optical structure of the plurality of optical structures such that the at least one etched mirror directs lased light toward the respective optical structure and the respective optical structure couples the lased light into the optical routing layer.

According to another aspect, a method for fabricating an optical chip is provided. In an example embodiment, the method includes providing a material stack comprising a first material layer having an optical element embedded therein, a second material layer disposed on the first material layer, and a third material layer disposed on the second material layer; forming a reflective region in the third material layer; forming a cavity region in the third material layer proximate the reflective region; and growing, following formation of the reflective region and the cavity region, a laser device within the cavity region, wherein the laser device is aligned with the reflective region such that an optical path is formed between the laser device and the optical element via the reflective region.

In another example embodiment, the method in includes forming a dielectric region onto an exposed surface of an optical routing layer of the optical chip, wherein the optical routing layer has a plurality of optical structures embedded therein; securing a support layer onto an exposed surface of the dielectric region; etching at least a first etched mirror and a first groove into an exposed surface of the support layer; and causing a first electrode, an active region including gain material, and a second electrode to be disposed within the groove. The active region is disposed between the first electrode and the second electrode such that applying a voltage difference between the first electrode and the second electrode causes the gain material to lase toward the first etched mirror. The first etched mirror is aligned with a respective optical structure of the plurality of optical structures such that the first etched mirror directs lased light toward the respective optical structure and the respective optical structure couples the lased light into the optical routing layer.

According to another aspect, an optical chip is provided. In an example embodiment, the optical chip includes a plurality of optical structures embedded within an optical routing layer. The plurality of optical structures comprising a first optical structure and a second optical structure. The optical chip further includes a support layer secured with respect to the optical routing layer. The support layer has a first etched mirror and a second etched mirror formed in an exposed surface of the support layer and a first groove and a second groove etched into the exposed surface of the support layer. The first etched mirror is aligned with the first optical structure and the first groove and the second etched mirror is aligned with the second optical structure and the second groove. The optical chip further includes a first electrode, an active region including gain material, and a second electrode disposed within the first groove. The active region is disposed between the first electrode and the second electrode such that applying a voltage difference between the first electrode and the second electrode causes the gain material to lase toward the first etched mirror. The first etched mirror directs lased light toward the respective optical structure and the respective optical structure couples the lased light into the optical routing layer. The second groove is configured to receive an optical fiber therein and the second optical structure is configured to direct light out of the optical routing layer toward the second etched mirror and the second etched mirror is configured to redirect the light toward the second groove.

### BRIEF DESCRIPTION OF THE SEVERAL VIEWS OF THE DRAWINGS

Reference will now be made to the accompanying drawings, which are not necessarily drawn to scale, and wherein:

FIG. 1A shows a side view of an optical chip with etched mirrors for optical fiber coupling, according to certain embodiments;

FIG. 1B shows a front view of the optical chip shown in FIG. 1A;

FIG. 2A shows a side view of another optical chip with etched mirrors for optical fiber coupling, according to certain embodiments;

FIG. 2B shows a front view of the optical chip shown in FIG. 2A;

FIG. 2C shows a side view of another optical chip according to certain embodiments;

FIG. 2D shows a front view of the optical chip shown in FIG. 2C;

FIG. 3 shows a side view of a partially manufactured optical chip according to certain embodiments;

FIG. 4 shows a side view of a partially manufactured optical chip having a grating coupler embedded within an optical routing layer according to certain embodiments;

FIG. 5 shows a side view of a material stack of a partially manufactured optical chip having an etched mirror formed in a support layer according to certain embodiments;

FIG. 6 provides a flowchart illustrating various processes and procedures for fabricating an optical chip with etched mirrors for optical fiber coupling, according to certain embodiments;

FIG. 7A shows a side view of an optical chip with integrated lasers, according to certain embodiments;

FIG. 7B shows a front view of the optical chip shown in FIG. 7A;

FIG. 8A shows a side cross-sectional view of an example integrated laser, according to certain embodiments;

FIG. 8B shows a front cross-sectional view of the example integrated laser shown in FIG. 8A;

FIG. 9A provides a flowchart illustrating various processes and procedures for fabricating an optical chip with integrated lasers, according to certain embodiments;

FIG. 9B provides a flowchart illustrating various processes and procedures for fabricating an optical chip with integrated lasers, according to certain embodiments;

FIG. 10 provides a side view of an optical chip including integrated lasers and etched mirrors for optical fiber coupling, according to certain embodiments;

FIG. 11 provides a flowchart illustrating various processes and procedures for fabricating an optical chip with integrated lasers and etched mirrors for optical fiber coupling, according to certain embodiments;

FIG. 12 provides a block diagram of an example system that may include one or more optical chips according to certain embodiments;

FIG. 13 provides a schematic diagram of an example datacenter that may include one or more optical chips according to certain embodiments; and

FIG. 14 provides a block diagram of two example communication devices in communication with one another according to certain embodiments.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide an optical chip configured to enable coupling of an array (e.g., a one-or two-dimensional array) of optical fibers to an edge of the optical chip and methods for fabrication thereof. In various embodiments, the optical chip includes a multi-dimensional (e.g., two-dimensional) array of grooves (e.g., V-grooves and/or the like) extending through an edge of the optical chip that are configured for receiving a multi-dimensional array of optical fibers therein. Etched mirrors in the optical chip direct light to and/or from the optical fibers to corresponding optical structures (e.g., grating couplers, mirrors, or other optical structures) that are configured to couple the light into or out of optical components (e.g., waveguides, etc.) of one or more optical routing layers of the optical chip.

For example, in various embodiments, an optical chip comprises a plurality of layers such as one or more insulating layers (e.g., an oxide layer, buried oxide layer, and/or the like), one or more optical routing layers (e.g., including various optical elements such as waveguides, grating couplers, mirrors, and/or the like), a dielectric layer or region (e.g., including various metallization layers and/or the like). A wafer (e.g., a silicon wafer or other semiconductor wafer) may be bonded to the optical chip to provide a support layer of the optical chip, and a mirror may be etched therein that aligns with an optical structure (e.g., grating coupler, mirror, and/or the like) embedded in the optical routing layer, for example. A groove, such as a V-groove, may be etched in the wafer that aligns with the etched mirror (which may have a metallic backing for 100% reflection, or may omit a metallic backing for partial reflection) such that an optical fiber may be secured into the groove such that an optical path is provided between an optical element disposed in the optical routing layer (e.g., a waveguide and/or the like) and the optical fiber via a grating coupler, mirror, or other optical structure embedded in the optical routing layer and the etched mirror that reflects/redirects (and focuses, in certain embodiments) light into the optical fiber. The optical routing layers can be for routing in a single direction, routing in multiple directions, or a combination of both single and multiple direction routing. Multiple wafers may be bonded to the optical chip to provide multiple support layers of the optical chip and to enable the formation of the multi-dimensional array of v-grooves that are each coupled to respective optical elements disposed in the optical routing layer via respective optical structures (e.g., embedded grating couplers or mirrors within the optical routing layer) and etched mirrors.

Generally, fiber-to-chip couplings require a stricter precision than is enabled by high-volume pick and place machines. For example, fiber-to-chip couplings may generally require a precision of 1 μm or less and the placement precision of high-volume pick and place machines is generally 1-3 μm. Moreover, because misalignment of optical components may be additive along an optical path, the precision required for attaching an optical fiber to a chip may be below 1 μm, if a complex optical path is used.

Historically, optical beams have been expanded using a lens/reflective optical surface that trades off X-Y plane tolerance for increased angular tolerance. These approaches often rely on vertical emission of light and thus require bulky mechanical ferrules and structures to provide fiber strain, rigidity, and alignment. The physical characteristics of these components (including the connector footprint and height clearance) are limiting in certain applications. Therefore, technical problems exist regarding fiber-to-chip attachment technologies that are scalable in a wide variety of applications.

Various embodiments provide technical solutions to these technical problems. For example, various embodiments provide one or more grooves, possibly a two-dimensional array of grooves, for securing optical fibers to an optical chip. Etched mirrors at least partially define respective optical paths between respective grooves and respective optical structures (e.g., couplers such as grating couplers and/or the like) configured to couple the respective optical paths into or out of respective optical components (e.g., waveguides, etc.) of the optical chip. The grooves enable optical fibers to be aligned with respective inputs/outputs of the optical chip with sufficient precision that light from an optical fiber may be efficiently coupled into an optical component of the optical chip via the etched mirror and the optical structure or that light from the optical component of the optical chip may be efficiently coupled into the optical fiber via the etched mirror and the optical structure. Therefore, various embodiments provide technical improvements to the technical fields of fiber-to-chip couplings, optical assemblies or systems including fiber-to-chip couplings, and/or the like.

Additional technical challenges related to optical chips include the integration of active components (e.g., comprising III-V semiconductor materials), such as lasers, into the optical chip architecture. For example, the epitaxial growth or hybrid bond of pre-grown III-V material on silicon-on-insulator (SOI) wafers used for integrated photonics presents both process compatibility and scalability challenges. Moreover, the contamination caused by processing III-V semiconductor material within an etching tool, for example, may cause the etching tool to be unusable for silicon-based material processing. Requirements for separate etching tools, for example, for specific processes leads to difficulties in volume scaling. Therefore, technical challenges exist with respect to integration of active components and/or photonics, such as lasers, with optical chips.

Various embodiments provide technical solutions to these technical problems. For example, various embodiments provide optical chips where the optical chip is fabricated, a support layer is secured thereto, etched mirrors and grooves are etched into a surface of the support layer, and lasers (or other active photonic components including III-V semiconductor material, for example) are formed in the grooves. Given that III-V semiconductor materials may contaminate CMOS fabrication tools, the proposed disclosure uses a “laser last” manufacturing process, where all CMOS manufacturing steps are performed in a first foundry prior to III-V semiconductor material growth in a second foundry. Further, according to conventional processes, growing III-V semiconductor materials on Si is difficult due to a mismatch of lattice constants of the materials. Although this can be alleviated via a buffer layer, conventional use of buffer layers may disrupt the optical path of the integrated photonic device. The present disclosure proposes optical devices structured to allow for self-alignment of the laser with the silicon integrated circuit and having a geometry where the buffer layer does not intersect the optical path to remedy the issues associated with the buffer layer. The etched mirrors are aligned with the grooves so as to redirect light emitted by a laser, for example, to an optical structure embedded in the optical routing layer of the optical chip. The optical structure embedded in the optical routing layer couples the light emitted by the laser into the optical routing layer for routing, processing, delivery to an appropriate receiver, and/or the like. Because all of the silicon-based material processing occurs prior to the growing or bonding of the III-V semiconductor material into the groove (to form the laser or other active photonic component) contamination may be prevented. Moreover, the laser or other active photonic component is self-aligned with a corresponding etched mirror configured to place the laser or other active photonic component in optical communication with a corresponding optical structure embedded in the optical routing layer of the optical chip. Various embodiments also allow for integration of a plurality of active photonic components (e.g., lasers and/or the like) into an optical chip and/or photonic integrated circuit (PIC). Therefore, various embodiments provide technical improvements to the technical fields of active photonic integration, optical assemblies or systems including integrated lasers, and/or the like.

### Example Optical Chip with Etched Mirrors for Optical Fiber Coupling

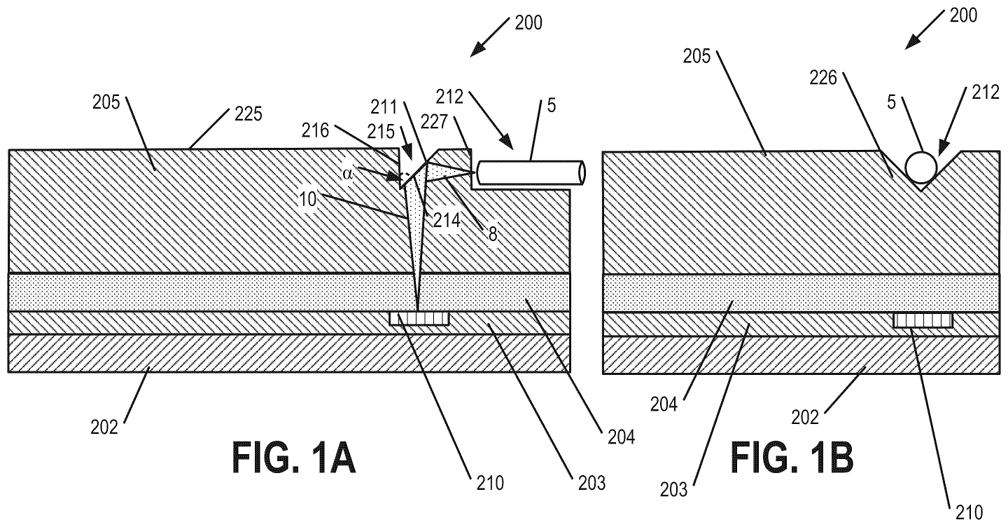

FIG. 1A provides a sideview of an example optical chip 200 and FIG. 1B provides a front view of the example optical chip 200. In various embodiments, the optical chip 200 includes a plurality of layers. For example, the illustrated optical chip 200 includes an insulating layer 202, an optical routing layer 203, a dielectric region 204, and a first support layer 205.

As used herein, the vertical direction is a direction that is normal to a surface of a layer (e.g., the insulating layer, the optical routing layer, the dielectric layer, a support layer, and/or the like) and a horizontal direction is a direction that is within a layer (e.g., parallel to a plane defined by a surface of a layer).

In various embodiments, the insulating layer 202 provides a base structure or substrate for the optical chip 200. In an example embodiment, the insulating layer 202 is an oxide layer or buried oxide layer. For example, the insulating layer 202 may comprise a material that is electrically insulating. In an example embodiment, the insulating layer has a thickness (in the vertical direction) of 1-2 μm and comprises one or more oxide and/or insulating materials.

In certain embodiments, the optical routing layer 203 is configured to route or guide optical signals through respective portions of the optical chip 200. For example, the optical routing layer 203 may include various optical components, such as waveguides and/or other guided mode optical components. For example, a plurality of waveguides, guided mode optical components, and/or other active and/or passive optical components may be patterned into the optical routing layer 203. In various embodiments, the optical routing layer 203 is a top silicon layer. The optical routing layer 203 has a thickness (in the vertical direction) of about 0.5 μm, in an example embodiment. In various embodiments, the optical components of the optical routing layer 203 include silicon and/or other materials, as appropriate for the application and the optical components present.

Additionally, one or more optical structures, such as couplers (e.g., grating couplers), mirrors, and/or other optical structures may be embedded and/or formed in the optical routing layer 203. For example, the illustrated optical chip 200 includes an optical structure in the form of grating coupler 210. The one or more optical structures may be configured to couple light propagating in a horizontal direction (e.g., within a layer and/or through an optical component of the optical routing layer 203 into a vertical direction (e.g., out of the layer). For example, the one or more optical structures may be configured to act as Bragg reflectors causing light propagating through the optical routing layer 203 to change direction to traverse vertical optical path portion 10. In another example, the one or more optical structures may be configured to couple light provided to the optical chip 200 via an optical fiber 5 such that the light traverses the horizontal optical path portion 8 and traverses the vertical optical path portion 10 into an optical component of the optical routing layer 203.

In various embodiments, the dielectric region 204 includes one or more electrical components of the optical chip 200. For example, the dielectric region 204 may include capping layers and any metallization layers (not shown). In various embodiments, one or more through vias may extend through the insulating layer 202 and the optical routing layer 203 to provide electrical contact to electrical components of the dielectric region 204. For example, solder pads on the exposed surface of the insulating layer 202 may be used to place the through-vias into electrical communication with various other components of an electro-optical system including the optical chip 200.

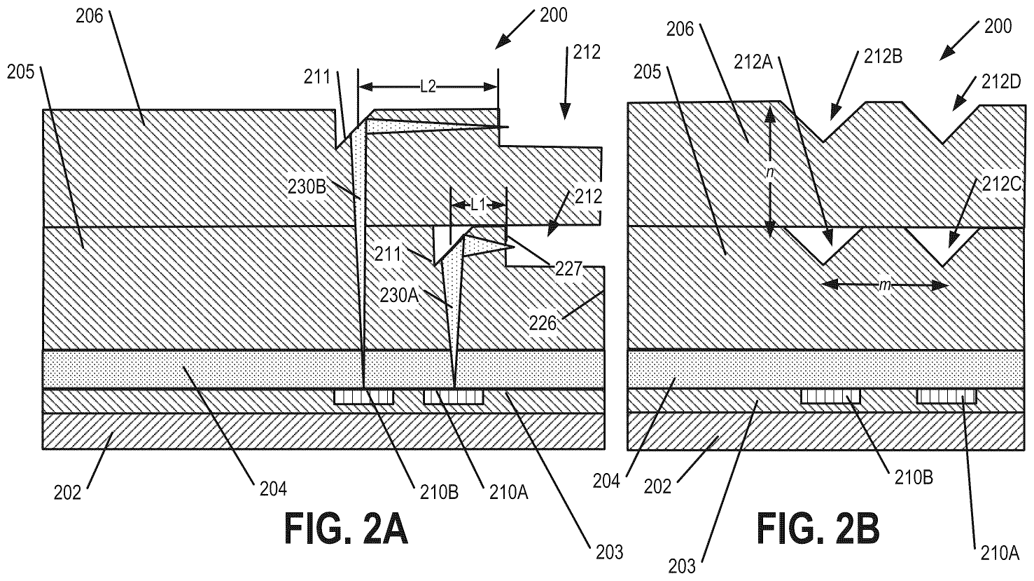

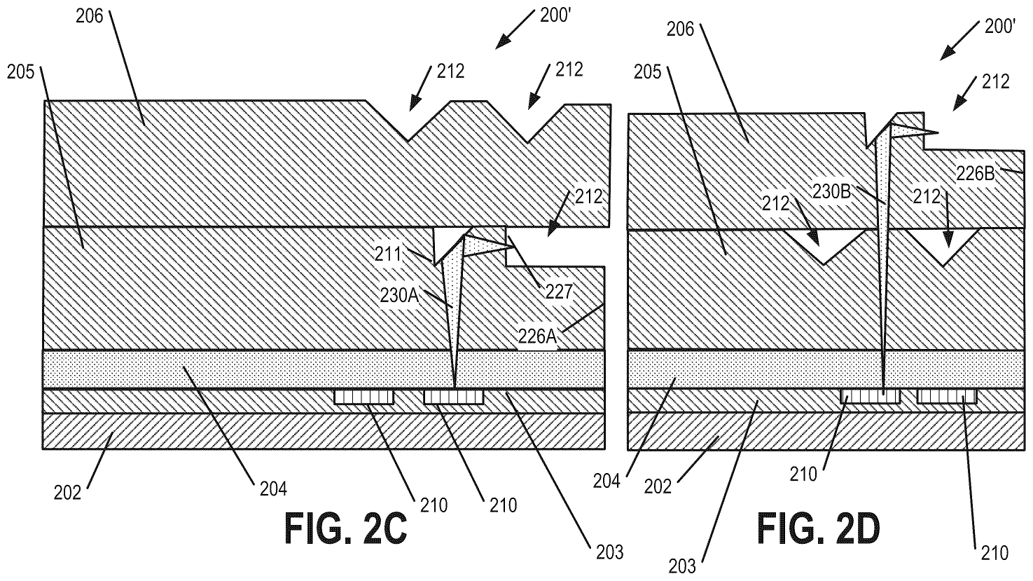

In various embodiments, a first support layer 205 is bonded to an exposed surface of the dielectric region 204. In various embodiments, a support layer, such as the first support layer 205, is a wafer, handle wafer, and/or the like. In various embodiments, a support layer (e.g., first support layer 205, second support layer 206 shown in FIGS. 2A and 2B) is a semiconductor wafer. For example, a support layer may comprise a semiconductor material such as Si, Ge, GaAs, GaN, and/or the like. For example, in some embodiments, the first support layer 205 is a standard silicon wafer. For example, the first support layer 205 may have a thickness of 750 μm. The first support layer 205 may be thinned (e.g., using traditional wafer thinning techniques such as etching, chemical mechanical polishing (CMP), and/or the like) to a desired thickness.

The first support layer 205 may be etched, patterned, and/or the like to form and/or define one or more grooves 212 and one or more etched mirrors 211 therein. The surface 225 of the support layer 205 refers to the flat planar areas on the top side (as illustrated in FIGS. 1A-2D and 5) of the wafer forming the support layer. The surface 225 is where the various layers of materials are deposited and/or where processing such as etching, doping, or photolithography occurs. The support layer 205 may be a permanent or temporary layer providing mechanical stability and that serves as a foundational layer to provide additional support to thin or delicate layers during manufacturing or processing. The support layer may be a thick, bulk layer that supports the thin layers (e.g., the optical routing layer 203, dielectric region 204, and/or the like) where the device functionality occurs.

In some embodiments, the grooves 212 are V-grooves. The exposed surface 225 of the first support layer 205 may be etched as shown in FIG. 1A to form an etched mirror 211. In various embodiments, an etched mirror is a reflective surface (e.g., mirror sidewall surface 214 formed within an etched cavity 215 in the exposed surface 225 of a support layer). To form the etched mirror 211, an etched cavity 215 may be etched into the exposed surface 225 of the first support layer 205 using grayscale lithography. In various embodiments, performing grayscale lithography includes varying the lithography laser power to change the depth of penetration to form an angled mirror sidewall surface 214 within the etched cavity 215 of the etched mirror 211. Alternatively, the thickness of a photoresist mask placed onto the exposed surface 225 of the support layer 205 may be varied across the area to be etched (while maintaining a constant UV laser power) to vary the depth of penetration of the laser to form the angled mirror sidewall surface 214 within the etched cavity 215 of the etched mirror 211.

The angled mirror sidewall surface 214 within the etched cavity 215 of the etched mirror 211 may have a square or rectangular perimeter, although it should be understood that other perimeter shapes may be etched, depending on the application of the optical chip. As shown, the angled mirrored sidewall may be provided at a 45 degree angle as shown in FIG. 1A, to redirect light from an at least substantially vertical direction (e.g., propagating along the vertical optical path portion 10) to an at least substantially horizontal direction (or vice versa) within the optical chip and parallel with a longitudinal axis of a groove 212 (also referred to herein as a horizontal optical path portion 8 or an in-plane optical path portion). In an example embodiment, the angled mirrored sidewall surface 214 forms an angle α with an opposing (substantially vertical) sidewall 216 of the etched cavity 215. In various embodiments, the angle α is at least ten degrees and less no more than eighty degrees. In certain embodiments, the angle α is in a range of thirty to sixty degrees. In some embodiments, such as that shown in FIG. 1A, the angle α is approximately forty-five degrees.

In certain embodiments, the mirror sidewall surface 214 is planar as illustrated in FIG. 1A. A planar mirrored sidewall serves to change the direction of the optical path (from the vertical optical path portion 10 leading from a respective optical structure such as the grating coupler 210 to a horizontal optical path portion 8 directed into the groove 212), but does not focus light traveling along the optical path. In other embodiments, the mirror sidewall surface 214 is curved to focus the light traveling along the optical path. The mirrored sidewall surface 214 may have a concave curvature, curved along a single axis (e.g., a horizontal axis) which serves to focus light to a single plane. In other embodiments, the mirrored sidewall surface 214 may have a concave curvature, curved along two axes (e.g., a vertical axis and a horizontal axis) to form a bowl-shape mirrored sidewall which serves to focus light to a single point. Where the mirrored sidewall surface 214 is curved (in one-dimension or two dimensions), the curvature of the sidewall may be optimized with the location of the groove 212 (formed with a separate etching step as discussed in greater detail herein), such that the focal length of the mirrored sidewall places its focal point at an end point of an optical fiber 5 to be placed within the groove 212.

Moreover, where the mirror sidewall surface 214 is curved (in one-dimension or in two-dimensions), the mirrored sidewall surface 214 may be formed in a single grayscale lithography etching step (e.g., where the depth of the photomask is varied using a gradient dosing procedure to form the curvature and the angle of the mirrored sidewall; or the power intensity of the lithography laser is varied to form the curvature and angle of the mirrored sidewall). In other embodiments, the mirrored sidewall surface 214 may be formed in multiple grayscale lithography etching steps. For example, a first grayscale lithography step may be performed to form a planar mirrored sidewall having an angle as shown in FIG. 1A, and a second grayscale lithography step may be performed on the planar mirrored sidewall to form a curvature. In certain embodiments, the second grayscale lithography step may be performed to form a single axis of curvature, or to form two axes of curvature within the mirrored sidewall surface 214.

In certain embodiments, a metallic coating may be applied onto the mirror sidewall surface 214 to increase the reflectivity of the mirrored sidewall surface. For example, gold, aluminum, silver, and/or the like may be applied using a thin-film application technique to provide complete reflectivity of light intersecting the mirror sidewall surface 214. However, it should be understood that certain embodiments may omit the metallic layer (thereby providing a silicon-air interface at the mirror sidewall surface 214), to provide a semi-reflective mirrored surface (e.g., which reflects a portion of the light to the groove 212 and transmits a portion of the light).

As shown in FIG. 1A, the etched mirror 211 is aligned with an optical structure, such as the grating coupler 210, in the optical routing layer 203. The illustrated grating coupler 210 acts as a Bragg reflector and turns the in-plane light in the optical routing layer 203 upwards as shown by the vertical optical path portion 10 extending upwards from the grating coupler 210 (note that up and down are directions provided in the orientation of the figures as a convenient orientation for discussion, but should not be construed as limiting the orientation in which optical chips 200 as discussed herein may be utilized). Moreover, the etched mirror 211 may be provided at a 45-degree angle within the exposed surface 225 of the first support layer 205 to redirect the optical path from a vertical orientation (e.g., vertical optical path portion 10) to a horizontal orientation (e.g., horizontal optical path portion 8). As mentioned, the use of a grating coupler 210 is an example, and other optical structures to redirect light from the optical routing layer 203 upwards and/or to couple light propagating along the vertical optical path portion 10 into the optical routing layer 203 may be utilized in certain embodiments (e.g., mirrors embedded within the optical routing layer 203).

The grating coupler 210 (or other optical structure that redirects light upwards) and the etched mirror 211 may be co-optimized to enable the correct optical mode diameter and reflective properties needed for a desired implementation. For example, in various embodiments, the etched mirror 211 and/or the grating coupler 210 (or other optical structure embedded in the optical routing layer 203) are configured to cause an optical beam that traverses an optical path defined, at least in part, by the grating coupler 210 and the etched mirror to have, in at least a portion of the corresponding groove 212, an optical mode diameter that matches the mode field diameter of an optical fiber 5. For example, the etched mirror 211 and/or the grating coupler 210 (or other optical structure embedded in the optical routing layer 203) may be configured to focus an optical beam onto an end of an optical fiber 5 secured within the corresponding groove 212 such that the optical mode diameter or waist of the optical beam at the end of the optical fiber 5 (within the groove 212) is approximately equal to the mode field diameter of the optical fiber 5.

In the illustrated embodiment, the etched mirror 211 is shown as a planar mirror surface, however it should be understood that in certain embodiments, the etched mirror 211 may be a curved surface, such as enabled by MEMS-based etch processes.

As shown in FIGS. 1A-1B, a groove 212 is etched into the exposed surface of the first support layer 205, for example, using wet etching techniques. In an example embodiment, the groove 212 is a V-groove. The groove 212 may be etched by applying a masking layer onto the exposed surface of the first support layer 205, with a gap in the masking corresponding to the size and location of the groove.

The groove 212 extends from an edge of the first support layer 205 (and from an overall edge of the optical chip 200), in a direction towards the etched mirror 211. The edge of the first support layer 205 is the outer perimeter or boundary of the wafer/first support layer 205. The edge typically includes the rounded or beveled part of the wafer that transitions between the top surface 225 and bottom surface (as illustrated in FIGS. 1A-1B) of the first support layer 205. A distal end of the groove (opposite the end of the groove 212 that is in the edge of the first support layer 205) is spaced a distance apart from the etched mirror 211, such that the horizontal optical path portion 8 passes through a portion of the first support layer 205 before passing into an interior of the groove 212. The distal end of the groove may be spaced apart from the mirrored sidewall surface 214 of the etched mirror 211 so that the focal length of the mirrored sidewall surface 214 is based on the distance between the etched mirror 211 and the groove 212, so that the focal point of the mirrored sidewall surface 214 is co-located with an end of an optical fiber 5 placed and/or secured within the groove 212 (for embodiments where the mirrored sidewall surface 214 has a concave curvature). Moreover, the depth of the groove may be provided such that an end of an optical fiber 5 placed within the groove 212 is aligned with the horizontal optical path portion 8 reflecting from the mirrored sidewall surface 214 of the etched mirror 211. It should be understood that the positioning and orientation of the etched mirror 211 and the groove 212 may be co-optimized so that light is reflected from the mirrored sidewall surface 214 of the etched mirror 211 into an optical fiber 5 placed within the groove 212. The angle and/or focal length of the mirrored sidewall surface 214 of the etched mirror 211 may be changed, so long as the depth and orientation of the groove is optimized so that light is reflected from the mirrored sidewall into an optical fiber 5 positioned within the groove. For example, different etched mirrors 211 of an optical chip 200 may have different angles and/or focal lengths, as shown in FIG. 2A.

An optical fiber 5 may be seated within the groove 212, such that light traveling along the illustrated optical path (including vertical optical path portion 10 and horizontal optical path portion 8) would be provided from the grating coupler 210, reflected off of the etched mirror 211 to an in-plane direction that is at least substantially parallel with the exposed surface of the support layer and directed into the groove 212, where it would pass into the optical fiber 5 mechanically mounted within the groove 212. For example, the groove 212, etched mirror 211, and grating coupler 210 (or another optical structure) define an optical path (consisting of the horizontal optical path portion 8 and the vertical optical path portion 10) that place an optical component (e.g., waveguide, guided mode optical component, and/or other optical component) of the optical routing layer 203 into optical communication with an optical fiber 5 seated within the groove 212.

In various embodiments, the optical chip 200 may be configured to include a two-dimensional array of grooves to enable a two-dimensional array of grating couplers to emit their light. For example, a two-dimensional array of optical structures (e.g., grating couplers, mirrors, and/or other optical structure) embedded in the optical routing layer 203 may be optically coupled to a two-dimensional array of optical fibers via a two-dimensional array of grooves 212.

In the illustrated embodiment of FIGS. 2A and 2B, a second support layer 206 is bonded onto the exposed surface of the first support layer 205. Moreover, a second grating coupler 210B is shown in the embodiments of FIGS. 2A-2B (although the inclusion of multiple grating couplers is merely an example-embodiments may utilize other optical structures to redirect light upwards (or may utilize a combination of one or more grating couplers and one or more other optical structures to redirect light upward, such as a mirror). Although the plurality of grating couplers 210 (including 210A, 210B) are aligned with one another in the embodiment of FIGS. 2A-2B (e.g., aligned along a single axis parallel to the side view in FIG. 2A, and perpendicular to the front view of FIG. 2B), it should be understood that other relative positions of the plurality of grating couplers 210 may be provided in other embodiments.

As shown in FIG. 2A, a first grating coupler 210A (located nearer to a first edge of the optical chip 200 than the second grating coupler 210B) is aligned with the etched mirror 211 in the first support layer 205, such that light from the first grating coupler 210A exits the optical chip 200 via the groove in the first support layer 205. As also shown in FIG. 2A, a second etched mirror 211 is etched in an exposed surface of the second support layer 206 (formed in an identical or similar manner as the etched mirror 211 of the first support layer 205 as discussed elsewhere herein) and is aligned with the second grating coupler 210B such that the optical path extending from the second grating coupler 210B reflects from the second etched mirror 211 in the second support layer 206 toward a second groove 212 etched in the exposed surface of the second support layer 206 (the second groove 212 etched in the exposed surface of the second support layer 206 in the same or a similar manner as the etching of the first groove 212 in the surface 225 of the first support layer 205).

In various embodiments, the first etched mirror 211 in the first support layer 205 is not aligned with the second etched mirror 211 in the second support layer 206 such that an optical path 230A defined at least in part by the first etched mirror 211 in the first support layer 205 does not intersect or overlap with an optical path 230B defined at least in part by the second etched mirror 211 in the second support layer 206. As shown, the etched mirror 211 of the first support layer 205 is spaced a distance L1 from a distal end 227 of the groove 212 in the first support layer 205, and the etched mirror 211 of the second support layer 206 is spaced a distance L2 (where L2 is greater than L1) from the distal end of the groove in the second support layer 206. In embodiments having this relative positioning between the etched mirrors 211 and corresponding grooves 212, the focal length of the etched mirror 211 in the second support layer 206 may differ from the focal length of the etched mirror 211 in the first support layer 205, to accommodate the differences between the distances L1 and L2. Accordingly, the radius of curvature of the mirrored sidewall surfaces may differ between the etched mirrors 211 in the first support layer 205 and second support layer 206.

Other configurations may be utilized to accommodate the differences in positioning of the etched mirrors. For example, the distance between the etched mirror 211 and the distal end of the groove may be manipulated (e.g., by lengthening the groove in the second support layer 206 relative to the first support layer 205, so that L1=L2), and the relative positioning of the optical fiber may be changed (e.g., such that the optical fiber in the second support layer 206 may seat further into the optical chip 200 as compared with the optical fiber in the first support layer 205.

As shown in FIG. 2B, a plurality of grooves 212 and corresponding etched mirrors (not shown in FIG. 2B, but aligned with the etched mirrors 211 visible in FIG. 2A) may be etched into each of the first support layer 205 and the second support layer 206. The plurality of grooves visible in FIG. 2B are staggered relative to one another, and the etched mirrors are similarly staggered as shown in FIG. 2A to avoid intersecting the optical paths of the plurality of grating couplers 210. Although not shown in FIG. 2B, a plurality of grating couplers 210 may be provided and spaced laterally (such that they would be adjacent and spaced from one another in the view of FIG. 2B).

In the embodiment of FIG. 2B, the plurality of grooves 212 (e.g., 212A, 212B, 212C, 212D) form a 2×2 array of grooves (with at least a first groove being vertically aligned with a second groove) to enable a 2-dimensional fiber array to be edge-coupled to the optical chip 200. For example, as shown in FIG. 2B, the first support layer 205 includes a first groove 212A and a third groove 212C and the second support layer 206 includes a second groove 212B and a fourth groove 212D. The first groove 212A, the second groove 212B, the third groove 212C, and the fourth groove 212D collectively define a two-dimensional array of grooves.

It should be understood that any of a variety of array shapes may be provided in other embodiments (e.g., a single groove in each layer may be offset relative to one another; 3 or more grooves may be provided in each layer, or different numbers of grooves may be provided in each layer). As an example, an optical chip 200 provided in accordance with various embodiments may have a n×m optical fiber connection into a single edge of the optical chip 200, wherein n>1 and n refers to the number of vertical layers within the optical fiber array (the n and m directions of the array are shown in FIG. 2B). As an example, the optical fiber connection on a single edge of an optical chip 200 may have a 2×1 array of optical fiber connections, wherein two-layers of optical fibers are stacked vertically within the edge of the optical chip 200. In certain embodiments, both n>1 and m>1. For example, n=2 and m=2 for a 2×2 groove array.

FIGS. 2A and 2B illustrate an example embodiment where a plurality of grooves (e.g., V-grooves) extending through a single edge 226 of the optical chip 200. However, it should be understood that grooves may extend through two or more edges of an optical chip 200 (e.g., through perpendicular edges of the optical chip, or through opposite edges of the optical chip 200). For example, FIGS. 2C and 2D illustrate an example embodiment of an optical chip 200′ where the grooves 212 formed in the first support layer 205 extend through a first edge 226A of the optical chip 200′ and the groves 212 formed in the second support layer 206 extend through a second edge 226B of the optical chip 200′. In the embodiment illustrated in FIGS. 2C and 2D, the first edge 226A and the second edge 226B are perpendicular to one another. In another embodiment, the first edge 226A and the second edge 226B may be opposite one another.

To direct the optical path from respective optical structures (e.g., grating couplers, mirrors, and/or other optical structures) embedded within the optical routing layer through different edges of the optical chip 200, 200′, the etched mirrors 211 may be oriented in different directions. It should be understood that in certain embodiments, the optical paths from multiple optical structures (e.g., grating couplers 210) do not intersect one another within the optical chip 200, 200′.

In various embodiments, the two or more support layers (e.g., first support layer 205, second support layer 206, and possibly additional support layers) are bonded together to form an optical interconnect for coupling a plurality of optical fibers to an optical chip 200, 200′. For example, the optical interconnect comprising the two or more support layers may be configured to couple a plurality of optical fibers to the optical chip 200, 200′ to which the two or more support layers are bonded.

For example, two or more support layers may provide an optical interconnect for coupling a plurality of optical fibers to an optical chip, where the optical interconnect includes two or more support layers bonded to one another with each support layer of the two or more support layers comprising at least one etched mirror 211 and at least one groove 212 configured to receive an optical fiber 5 of the plurality of optical fibers therein. The at least one etched mirror is configured to at least partially define an optical path between the at least one groove and a corresponding optical structure embedded in an optical routing layer 203 of the optical chip 200, 200′. In certain embodiments, least one of the at least one etched mirror 211 or the corresponding optical structure (e.g., grating coupler 210) is configured to cause an optical beam that traversed the optical path to have, within at least a portion of the groove 212 (e.g., at an end of the optical fiber 5), an optical mode diameter or waist that matches a mode field diameter of the optical fiber 5.

In the embodiments discussed herein, the wafer-to-wafer bonding uses fine alignment (having a precision with a tolerance of tens of nanometers) to ensure the support layers are precisely placed relative to one another. Moreover, high-accuracy etch processes are utilized to enable accurate optical coupling into an optical fiber. The groove, formed by a wet etch process, for example, enables mechanical registration of the optical fiber to have high accuracy of alignment to the optical beam exiting the edge of the optical chip 200.

### Example Method of Manufacturing Optical Chip with Etched Mirrors for Optical Fiber Coupling

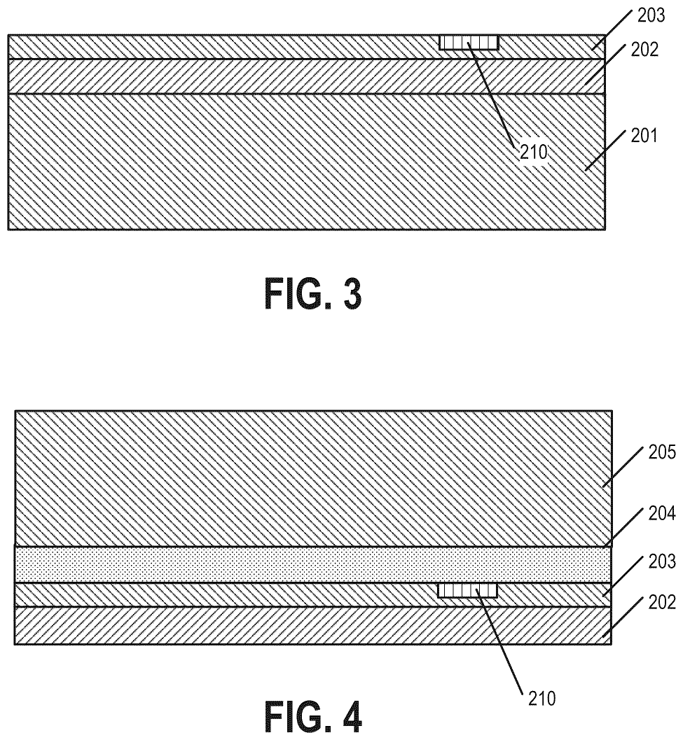

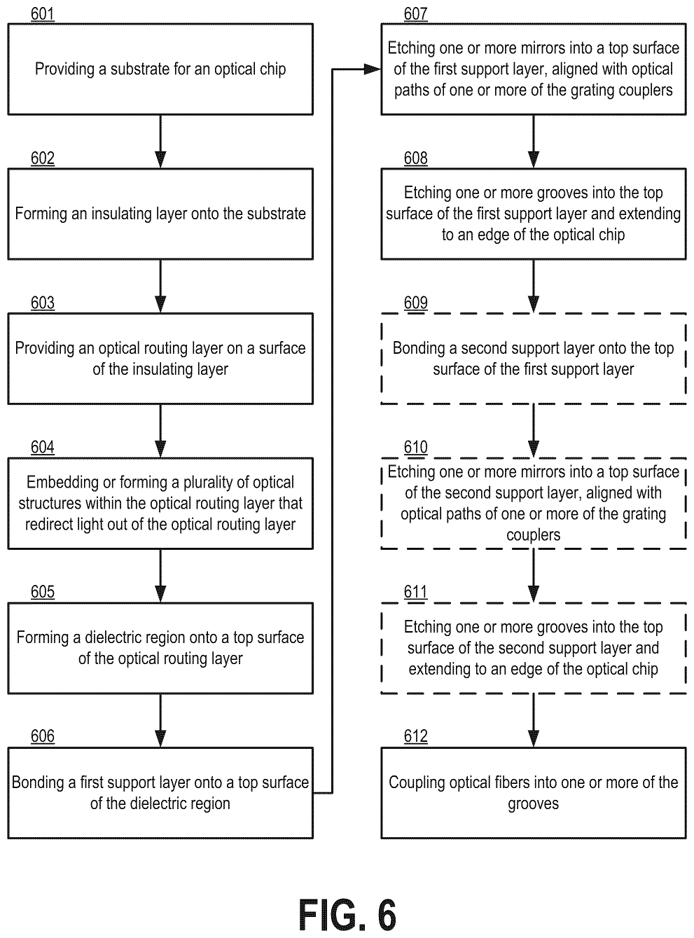

FIG. 6 illustrates an example method of manufacturing an optical chip as illustrated in FIGS. 1A-2B. FIGS. 3-5 illustrate the results of performing various processes and/or procedures shown in FIG. 6.

FIG. 6 illustrates steps 601-612, which provides for two support layers each having one or more etched mirrors and etched grooves therein. It should be understood that an optical chip having a single support layer with one or more etched mirrors and grooves may be provided by omitting steps 609-611 of the illustrated process. Moreover, additional support layers, each having one or more etched mirrors and grooves may be formed by repeating steps 609-612 as many times as desired.

As shown, the method of FIG. 6 begins at 601, where a substrate or wafer is provided for an optical chip. In an example embodiment, the substrate or wafer is a bulk silicon layer. For example, the substrate or wafer may be a standard silicon wafer, a specifically designed silicon wafer, and/or another wafer or substrate.

At step 602, an insulating layer is formed onto the substrate or wafer. For example, an insulating material layer may be deposited onto the substrate or wafer. For example, a layer of insulating material (e.g., oxide and/or the like) may be deposited onto the substrate or wafer to form an insulating layer. The insulating layer may include one or more oxide and/or insulating materials.

At step 603, an optical routing layer is bonded, deposited, patterned, and/or grown onto an exposed surface of the buried oxide layer and patterned. For example, the optical routing layer may be patterned to include one or more optical components (e.g., waveguides, guided mode optical components, and/or the like). In various embodiments, the optical routing layer is patterned to include optical components in accordance with a designed architecture appropriate for the intended application of the optical chip.

One or more optical structures, such as grating couplers 210 may be embedded, formed, and/or patterned within the optical routing layer, as shown at 604. It should be understood that other optical structures may be used in the alternative to grating couplers 210, such as forming mirrors within the optical routing layer that serve to redirect light out of the optical routing layer (e.g., upwards as illustrated in FIGS. 1A-2B). As just one alternative to embedding a grating coupler within the optical routing layer, a mirror may be etched into the top surface of the grating coupler, such as by using grayscale lithography in a manner as discussed herein with reference to other etched mirrors, that serves to redirect light from in-plane components within the optical routing layer upwards towards an etched mirror within a later-formed support layer. Other components may be embedded and/or otherwise formed within the optical routing layer, as desired based on the optical chip design. For example, the optical routing layer may include various optical components such as waveguides and/or grating couplers 210.

FIG. 3 illustrates a result of performing step 604. For example, FIG. 3 illustrates a substrate 201, an insulating layer 202 formed and/or deposited onto the substrate 201, an optical routing layer 203 formed and/or patterned on the insulating layer 202, and one or more optical structures, such as grating coupler 210 embedded, formed and/or patterned within the optical routing layer 203.

Continuing with FIG. 6, a dielectric region (comprising one or more capping layers and/or metallization layers) is provided onto the optical routing layer, as shown at step 605. For example, the dielectric region may be deposited, patterned, formed, and/or bonded onto the optical routing layer. In various embodiments, the dielectric region is fabricated in accordance with an architecture of the optical chip which is appropriate for the intended application.

A first support layer is bonded onto the dielectric region, as shown at step 606. For example, a wafer-to-wafer bonding technique may be used to bond the first support layer onto the dielectric region. Where applicable, the first support layer may be thinned to a desired thickness.

In certain embodiments, the substrate may be removed after the first support layer is bonded onto the dielectric region. One or more through-vias may be formed through a surface of the insulating layer that was exposed due to removal of the substrate. The one or more through-vias may be configured to provide electrical connection and/or communication with one or more components of the dielectric region.

For example, completion of steps 601-606 may provide an optical chip 200 having a support layer bonded thereto, as shown in FIG. 4. For example, FIG. 4 illustrates an optical chip 200 including an insulating layer 202, an optical routing layer 203, formed on the insulating layer 202, a grating coupler 210 formed and/or embedded in the optical routing layer 203, a dielectric region 204 provided on the optical routing layer 203, and a first support layer 205 bonded to the dielectric region 204. The substrate 201 has been removed (e.g., via etching and/or the like).

For example, in various embodiments, after bonding the first support layer 205 to the dielectric region 204, an etching is performed to remove the substrate 201. In an example embodiment, one or more through-vias providing electrical contact to components of the dielectric region 204 may be formed through the insulating layer 202 and optical routing layer 203.

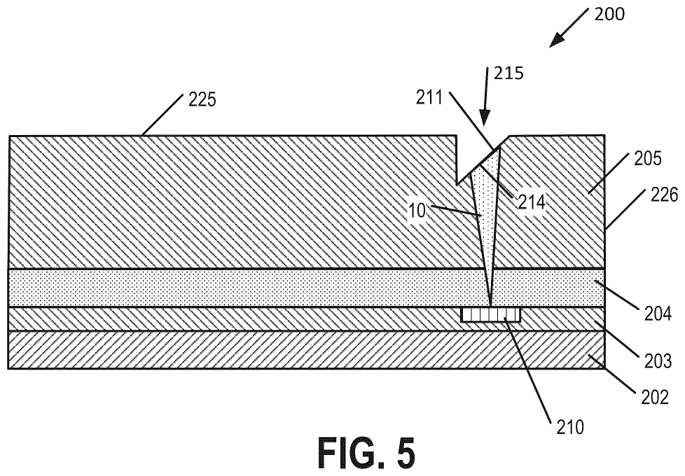

After bonding of the first support layer 205 to the dielectric region, the first support layer 205 may be patterned to include one or more grooves and one or more etched mirrors that, along with the optical structures such as grating coupler 210, provide respective optical paths between optical components of the optical routing layer 203 and optical fibers 5 inserted into the grooves 212. For example, continuing with FIG. 6, at 607, one or more etched mirrors 211 are etched into a surface 225 of the first support layer 205. As discussed herein, the etched mirrors may be formed using grayscale lithography. As one example, a power intensity gradient of a lithography laser may be used to form an angled mirror sidewall surface 214 or surface as shown in FIG. 5 within the etched cavity 215. As another example, a photoresist layer may be applied to a top surface of the support layer using a gradient dosing method to adjust the depth of penetration of a lithography laser etching the etched cavity 215.

In certain embodiments, the mirror sidewall surface 214 of the etched cavity 215 may be planar or the mirrored sidewall may have a concave curvature (with a single axis of curvature or two axes of curvature). For curved mirrored sidewalls, the etching may be performed in a single step (for both forming the etched cavity 215 and forming the curvature within the mirrored sidewall surface 214) or the etching may be performed in a plurality of sequential steps (e.g., first forming a planar mirrored sidewall surface, and then forming a curvature within the mirrored sidewall surface in one or more grayscale lithography etching steps).

In certain embodiments, a metal coating is applied onto the mirror sidewall surface 214 to increase reflectivity of the mirrored sidewall surface. The metal may be gold, aluminum, silver, or other reflective metals that may be deposited in a thin-film onto the mirrored sidewall surface within the etched cavity 215 of the etched mirror 211.

The resulting mirror sidewall surface 214 is angled (and/or curved) to redirect (and/or refocus) light from a vertical optical path portion 10 (e.g., extending vertically from a grating coupler 210 or other optical structure within the optical routing layer) to a horizontal optical path portion 8 (also referred to herein as an in-plane optical path) that is at least substantially parallel with the surface 225 of the first support layer and is directed into an optical fiber disposed within the groove. It should be understood that the angle and/or focal point of the mirror sidewall surface 214 may be optimized together with the location and/or depth of the groove 212 to direct light from the grating coupler 210 into an optical fiber placed within the groove. In an example embodiment, completion of step 607 provides an optical chip 200 as illustrated in FIGS. 1A and 1B.

Continuing at 608, one or more grooves 212 are etched into the exposed surface 225 of the first support layer 205 and extending to an edge 226 of the first support layer 205 (which also defines the edge of the optical chip). In various embodiments, the grooves 212 are V-grooves or another appropriate groove. Masking and wet etching, or other appropriate etching methodologies, may be utilized to form the grooves 212. The grooves 212 are aligned with the horizontal optical path portion 8 of a corresponding etched mirror 211, such that light reflected from the etched mirror 211 travels parallel with a longitudinal plane extending along a length of the groove 212 between the edge 226 of optical chip 200 to an opposite distal end 227 of the groove 212. It should be understood that the order of etching the etched mirror and the grooves may be reversed to achieve the same result. For example, in some embodiments, step 608 may be performed before step 607.

Where a single support layer is to be provided with the optical chip, the process skips to 612, where optical fibers 5 are coupled within the grooves 212 to capture light reflected from the etched mirrors and/or to provide light to the etched mirrors. For example, completion of steps 601-608 and 612 may provide an optical chip as illustrated in FIGS. 1A and 1B.

In various embodiments, an optical chip may include a plurality of support layers providing a two-dimensional array of grooves for use in coupling optical fibers to the optical chip. In such embodiments, the process continues from step 608 to step 609. At step 609 of FIG. 6, for optical chips having at least a second support layer 206, the second support layer is bonded (using wafer-to-wafer bonding techniques) onto the exposed surface 225 of the first support layer 205.

At step 610, one or more etched mirrors 211 are etched within the exposed surface of the second support layer 206, in a manner similar to that discussed above with respect to step 607 of FIG. 6 (including the possible application of a metal layer onto the mirror sidewall surface 214 within the etched cavity 215 of the etched mirror 211). The etched mirrors within the second support layer are staggered relative to the etched mirrors within the first support layer, such that the optical paths extending to the etched mirrors of the first support layer do not intersect the optical paths extending to the etched mirrors of the second support layer. Moreover, by staggering the etched mirrors to vary the distance between the etched mirrors and the edge of the optical chip 200 as shown in FIG. 2A, the focal point of the etched mirror may be at a different focal length away from the etched mirror in each support layer. The focal length of the etched mirrors in each layer may differ by varying the radius of curvature of the mirrored surfaces in each layer.

At step 611, one or more grooves 212 are etched into the exposed surface of the second support layer 206 in a manner similar to that discussed above in reference to step 608. In certain embodiments, the length of the grooves of the second support layer may be identical to the length of the grooves of the first support layer (measured between the edge of the optical chip to the distal end of the groove, measured along the central plane that extends along the length of the groove). In other embodiments, the length of the grooves 212 within the second support layer 206 may differ from the length of the grooves 212 within the first support layer 205.

Where more than two support layers are to be provided for the optical chip (each having etched mirrors and grooves therein), the processes of steps 609-611 may be repeated until the desired number of support layers are provided. As shown at step 612, optical fibers are coupled into the grooves formed in the preceding steps. It should be understood that the optical fibers may be coupled at any point after formation of the grooves. For example, the optical fibers may be mechanically secured into the grooves 212.

### Example Optical Chip with Integrated Active Photonics

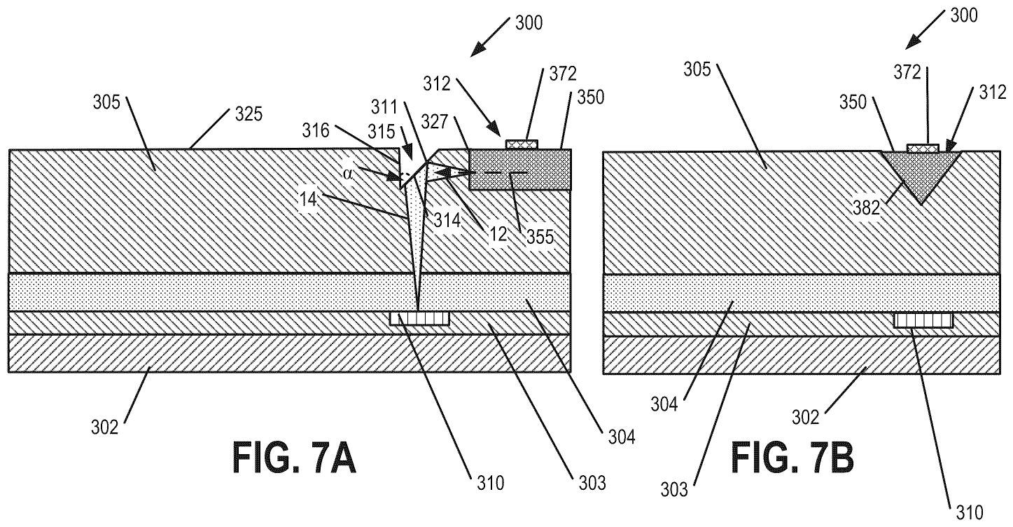

FIG. 7A provides a side cross-sectional view of an example optical chip 300 and FIG. 7B provides a front cross-sectional view of the example optical chip 300. In various embodiments, the optical chip 300 includes a plurality of layers. For example, the illustrated optical chip 300 includes an insulating layer 302, an optical routing layer 303, a dielectric region 304, and a support layer 305.

As used herein, the vertical direction is a direction that is normal to a surface of a layer (e.g., the insulating layer, the optical routing layer, the dielectric layer, a support layer, and/or the like) and a horizontal direction is a direction that is within a layer (e.g., parallel to a plane defined by a surface of a layer).

In various embodiments, the insulating layer 302 provides a base structure or substrate for the optical chip 300. In an example embodiment, the insulating layer 302 is an oxide layer or buried oxide layer. For example, the insulating layer 302 may comprise a material that is electrically insulating. In an example embodiment, the insulating layer has a thickness (in the vertical direction) of 1-2 μm and comprises one or more oxide and/or insulating materials.

In certain embodiments, the optical routing layer 303 is configured to route or guide optical signals through respective portions of the optical chip 300. For example, the optical routing layer 303 may include various optical components, such as waveguides and/or other guided mode optical components. For example, a plurality of waveguides, guided mode optical components, and/or other active and/or passive optical components may be patterned into the optical routing layer 303. In various embodiments, the optical routing layer 303 is a top silicon layer. The optical routing layer 303 has a thickness (in the vertical direction) of about 0.5 μm, in an example embodiment. In various embodiments, the optical components of the optical routing layer 303 include silicon and/or other materials, as appropriate for the application and the optical components present.

Additionally, one or more optical structures, such as couplers (e.g., grating couplers), mirrors, and/or other optical structures may be embedded and/or formed in the optical routing layer 303. For example, the illustrated optical chip 300 includes an optical structure in the form of grating coupler 310. The one or more optical structures may be configured to couple light propagating in a vertical direction (e.g., toward the optical routing layer 303 from the etched mirror 311 into a horizontal direction (e.g., into a layer and/or an optical component of the optical routing layer 303). For example, the one or more optical structures may be configured to act as Bragg reflectors causing light propagating along a vertical optical path portion 14 to be coupled into the optical routing layer 303. For example, the one or more optical structures may be configured to couple light provided to the optical chip 300 via an integrated laser 350 (e.g. epitaxially grown) such that the light traverses the horizontal optical path portion 12 and traverses the vertical optical path portion 14 into an optical component of the optical routing layer 303. While the optical chip 300 is shown as including only one integrated laser 350, it should be understood that in various embodiments, an optical chip may include a plurality of integrated lasers 350 (and/or other active photonic components) as appropriate for the application.

In various embodiments, the dielectric region 304 includes one or more electrical components of the optical chip 300. For example, the dielectric region 304 may include capping layers and any metallization layers (not shown). In various embodiments, one or more through vias may extend through the insulating layer 302 and the optical routing layer 303 to provide electrical contact to electrical components of the dielectric region 304. For example, solder pads on the exposed surface of the insulating layer 302 may be used to place the through-vias into electrical communication with various other components of an electro-optical system including the optical chip 300.

In various embodiments, a support layer 305 is bonded to an exposed surface of the dielectric region 304. In various embodiments, a support layer 305 is a wafer, handle wafer, and/or the like. In various embodiments, a support layer 305 is a semiconductor wafer. For example, a support layer may comprise a semiconductor material such as Si, Ge, GaAs, GaN, and/or the like. For example, in some embodiments, the support layer 305 is a standard silicon wafer. For example, the support layer 305 may have a thickness of 750 μm. The support layer 305 may be thinned (e.g., using traditional wafer thinning techniques such as etching, chemical mechanical polishing (CMP), and/or the like) to a desired thickness.

The support layer 305 may be etched, patterned, and/or the like to form and/or define one or more grooves 312 and one or more etched mirrors 311 therein. The surface 325 of the support layer 305 refers to the flat planar areas on the top side (as illustrated in FIGS. 7A-7B) of the wafer forming the support layer. The surface 325 is where the various layers of materials are deposited and/or where processing such as etching, doping, or photolithography occurs. The support layer 305 may be a permanent or temporary layer providing mechanical stability and that serves as a foundational layer to provide additional support to thin or delicate layers during manufacturing or processing. For example, The support layer may be a thick, bulk layer that supports the thin layers (e.g., the optical routing layer 303, dielectric region 304, and/or the like) where the device functionality occurs.

In some embodiments, the grooves 312 are V-grooves. The exposed surface 325 of the support layer 305 may be etched as shown in FIG. 7A to form an etched mirror 311. In various embodiments, an etched mirror is a reflective surface (e.g., mirror sidewall surface 314 formed within an etched cavity 315 in the exposed surface 325 of a support layer). To form the etched mirror 311, an etched cavity 315 may be etched into the exposed surface 325 of the support layer 305 using grayscale lithography. In various embodiments, performing grayscale lithography includes varying the lithography laser power to change the depth of penetration to form an angled mirror sidewall surface 314 within the etched cavity 315 of the etched mirror 311. Alternatively, the thickness of a photoresist mask placed onto the exposed surface 325 of the support layer 305 may be varied across the area to be etched (while maintaining a constant UV laser power) to vary the depth of penetration of the laser to form the angled mirror sidewall surface 314 within the etched cavity 315 of the etched mirror 311.

The angled mirror sidewall surface 314 within the etched cavity 315 of the etched mirror 311 may have a square or rectangular perimeter, although it should be understood that other perimeter shapes may be etched, depending on the application of the optical chip. As shown, the angled mirrored sidewall may be provided at a 45 degree angle as shown in FIG. 7A, to redirect light from an at least substantially vertical direction (e.g., propagating along the vertical optical path portion 14) to an at least substantially horizontal direction (or vice versa) within the optical chip and parallel with a longitudinal axis of a groove 312 (also referred to herein as a horizontal optical path portion 12 or an in-plane optical path portion). In an example embodiment, the angled mirrored sidewall surface 314 forms an angle α with an opposing (substantially vertical) sidewall 316 of the etched cavity 315. In various embodiments, the angle α is at least ten degrees and less no more than eighty degrees. In certain embodiments, the angle α is in a range of thirty to sixty degrees. In some embodiments, such as that shown in FIG. 7A, the angle α is approximately forty-five degrees.

In certain embodiments, the mirror sidewall surface 314 is planar as illustrated in FIG. 7A. A planar mirrored sidewall serves to change the direction of the optical path (from the vertical optical path portion 14 leading from a respective optical structure such as the grating coupler 310 to a horizontal optical path portion 12 directed into the groove 312), but does not focus light traveling along the optical path. In other embodiments, the mirror sidewall surface 314 is curved to focus the light traveling along the optical path. The mirrored sidewall surface 314 may have a concave curvature, curved along a single axis (e.g., a horizontal axis) which serves to focus light to a single plane. In other embodiments, the mirrored sidewall surface 314 may have a concave curvature, curved along two axes (e.g., a vertical axis and a horizontal axis) to form a bowl-shape mirrored sidewall which serves to focus light to a single point. Where the mirrored sidewall surface 314 is curved (in one-dimension or two dimensions), the curvature of the sidewall may be optimized with the location of the groove 312 (formed with a separate etching step as discussed in greater detail herein), such that the focal length of the mirrored sidewall places its focal point within the groove 312 and/or within the optical structure such grating coupler 310.

Moreover, where the mirror sidewall surface 314 is curved (in one-dimension or in two-dimensions), the mirrored sidewall surface 314 may be formed in a single grayscale lithography etching step (e.g., where the depth of the photomask is varied using a gradient dosing procedure to form the curvature and the angle of the mirrored sidewall; or the power intensity of the lithography laser is varied to form the curvature and angle of the mirrored sidewall). In other embodiments, the mirrored sidewall surface 314 may be formed in multiple grayscale lithography etching steps. For example, a first grayscale lithography step may be performed to form a planar mirrored sidewall having an angle as shown in FIG. 7A, and a second grayscale lithography step may be performed on the planar mirrored sidewall to form a curvature. In certain embodiments, the second grayscale lithography step may be performed to form a single axis of curvature, or to form two axes of curvature within the mirrored sidewall surface 314.

In certain embodiments, a metallic coating may be applied onto the mirror sidewall surface 314 to increase the reflectivity of the mirrored sidewall surface. For example, gold, aluminum, silver, and/or the like may be applied using a thin-film application technique to provide complete reflectivity of light intersecting the mirror sidewall surface 314. However, it should be understood that certain embodiments may omit the metallic layer (thereby providing a silicon-air interface at the mirror sidewall surface 314), to provide a semi-reflective mirrored surface (e.g., which reflects a portion of the light to the groove 312 and transmits a portion of the light).

As shown in FIG. 7A, the etched mirror 311 is aligned with an optical structure, such as the grating coupler 310, in the optical routing layer 303. The illustrated grating coupler 310 acts as a Bragg reflector and turns the light propagating along the vertical optical path portion into the optical routing layer 303. Moreover, the etched mirror 311 may be provided at a 45-degree angle within the exposed surface 325 of the support layer 305 to redirect the optical path from a horizontal orientation (e.g., horizontal optical path portion 12) to a vertical orientation (e.g., vertical optical path portion 14). As mentioned, the use of a grating coupler 310 is an example, and other optical structures to couple light propagating along the vertical optical path portion 14 into the optical routing layer 303 may be utilized in certain embodiments (e.g., mirrors embedded within the optical routing layer 303).

The grating coupler 310 (or other optical structure configured to couple light into the optical routing layer 303) and the etched mirror 311 may be co-optimized to enable the correct optical mode diameter and reflective properties needed for a desired implementation. For example, in various embodiments, the etched mirror 311 and/or the grating coupler 310 (or other optical structure embedded in the optical routing layer 303) are configured to cause an optical beam that traverses an optical path defined, at least in part, by the etched mirror 311 and the grating coupler 310 and the etched mirror to have, when the light is coupled into the optical routing layer 303, an optical mode diameter that matches the mode field diameter of an optical component (e.g., waveguide, guided mode optical component, and/or other optical component) of the optical routing layer 303. For example, the etched mirror 311 and/or the grating coupler 310 (or other optical structure embedded in the optical routing layer 303) may be configured to focus an optical beam into an optical component (e.g., waveguide, guided mode optical component, and/or other optical component) of the optical routing layer 303 such that the optical mode diameter or waist of the optical beam when the optical beam is coupled into the optical component is approximately equal to the mode field diameter of the optical component of the optical routing layer 303.

In the illustrated embodiment, the etched mirror 311 is shown as a planar mirror surface, however it should be understood that in certain embodiments, the etched mirror 311 may be a curved surface, such as enabled by MEMS-based etch processes.

As shown in FIGS. 7A-7B, a groove 312 is etched into the exposed surface of the support layer 305, for example, using wet etching techniques. In an example embodiment, the groove 312 is a V-groove. For example, the top surface 325 of the support layer 305 may be a <1,0,0> plane of the material of the support layer 305 and groove 312 may be etched to expose a <1,1,1> plane of the material of the support layer 305. The groove 312 may be etched by applying a masking layer onto the exposed surface of the support layer 305, with a gap in the masking corresponding to the size and location of the groove.

The groove 312 extends from an edge of the support layer 305 (and from an overall edge of the optical chip 300), in a direction towards the etched mirror 311. The edge of the support layer 305 is the outer perimeter or boundary of the wafer/support layer 305. The edge typically includes the rounded or beveled part of the wafer that transitions between the top surface 325 and bottom surface (as illustrated in FIGS. 7A-7B) of the support layer 305. A distal end 327 of the groove 312 (opposite the end of the groove 312 that is in the edge of the support layer 305) is spaced a distance apart from the etched mirror 311, such that the horizontal optical path portion 12 passes through a portion of the support layer 305 between the groove 312 and the etched mirror 311. The distal end 327 of the groove may be spaced apart from the mirrored sidewall surface 314 of the etched mirror 311 so that the focal length of the mirrored sidewall surface 314 is based on the distance between the etched mirror 311 and the groove 312. In some instances, the focal length of the mirrored sidewall surface 314 is based on the distance between the etched mirror 311 and the corresponding optical structure, such as the grating coupler 310 (for embodiments where the mirrored sidewall surface 214 has a concave curvature).

Moreover, the depth of the groove may be provided such that an output of a laser or other active optical component formed and/or disposed within the groove 312 is aligned with the horizontal optical path portion 12 such that light emitted by the laser (along the optical axis 355 of the laser 350) reflects from the mirrored sidewall surface 314 of the etched mirror 311 onto the vertical optical path portion 14 toward the corresponding optical structure (e.g., grating coupler 310).

It should be understood that the positioning and orientation of the etched mirror 311, the optical structure (e.g., grating coupler 310, mirror, and/or the like), and the groove 312 may be co-optimized so that light is reflected from the mirrored sidewall surface 314 of the etched mirror 311 and is coupled into the optical routing layer via the optical structure (e.g., grating coupler 310, mirror, and/or the like). The angle and/or focal length of the mirrored sidewall surface 314 of the etched mirror 311 may be changed, so long as the depth and orientation of the groove 312 and/or the optical structure (e.g., grating coupler 310, mirror, and/or the like) is optimized so that light is reflected from the mirrored sidewall surface 314 to the optical structure (e.g., grating coupler 310, mirror, and/or the like) embedded in the optical routing layer 303. For example, different etched mirrors 311 of an optical chip 300 may have different angles and/or focal lengths.

In various embodiments, one or more active photonic components may be formed and/or disposed within respective grooves 312 of the optical chip 300. For example, each active photonic component may be in optical communication with a respective etched mirror 311 via a horizontal optical path portion 12, and the respective etched mirror 311 may be in optical communication with a respective optical structure (e.g., grating coupler 310, mirror, and/or the like) via a vertical optical path portion 14. In this manner, the active photonic component formed and/or disposed within a groove 312 may provide or receive optical signals, beams, and/or light to/from the optical routing layer 303.

In various embodiments, the active photonic components include III-V semiconductor material. For example, the active photonic component may be a laser 350 that includes a first electrode, gain material, and a second electrode and at least one of the first electrode, gain material, or the second electrode may include III-V semiconductor material.

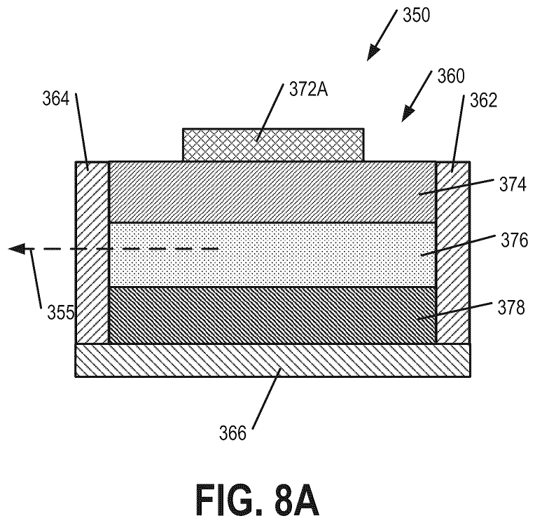

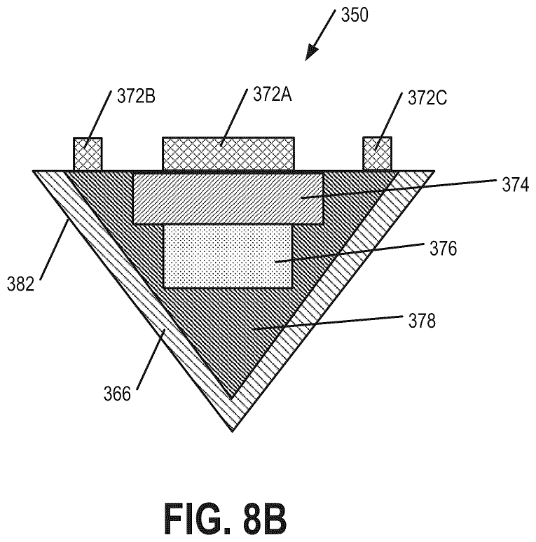

FIGS. 8A-8B provide cross-sectional side and front views of an example laser 350 that may be formed and/or disposed in a groove 312 of an optical chip 300. The laser 350 is configured to emit and/or lase light along an optical axis 355 that is directed toward to the etched mirror 311. An optical cavity 360 is defined within the groove 312 by first cavity mirror 362 and second cavity mirror 364. In various embodiments, the second cavity mirror 364 is located between the etched mirror 311 and the first cavity mirror 362 along the optical axis 355 of the laser. The second cavity mirror 364 is configured to be a partial reflectivity mirror. For example, the reflectance of the second cavity mirror 364 may be less than 100% (but at least 50% in certain embodiments) such that light may be emitted through the second cavity mirror 364. The first cavity mirror 362 has a reflectance that is larger than the reflectance of the second cavity mirror 364.

The laser 350 comprises a first electrode 374, active region 376, and a second electrode 378. In an example embodiment, the first electrode 374 is an anode and the second electrode 378 is a cathode. In one embodiment, the first electrode 374 is a cathode and the second electrode 378 is an anode. The active region 376 is disposed between the first electrode 374 and the second electrode 378. In various embodiments, one of the first electrode 374 or the second electrode 378 comprises a P-doped material and the other of the first electrode 374 or the second electrode 378 comprises an N-doped material.

In various embodiments, the active region 376 is disposed between the first electrode 374 and second electrode 378 and comprises gain material. In various embodiments, the gain material comprises a stack of quantum well and/or quantum dot layers. In an example embodiment, the active region 376 comprises one or more active layers of gain material such as an InGaAs-based material, a GaAs-based material, or other material configured to generate light of a characteristic wavelength of integrated laser 350.

In various examples, the active region 376 comprises a plurality of quantum wells where light is generated between the first cavity mirror 362 and the second cavity mirror 364. In some examples, the active region 376 comprises multi-quantum well and/or dots layers (MQLs) of gain material. For example, the MQLs may comprise a stack or a series of quantum wells disposed between a series of (quantum) barriers. In various embodiments, the MQLs are configured to generate light that is similar in wavelength to the characteristic wavelength of the laser 350. In various embodiments, the MQLs are configured to generate light having a wavelength in the 700-2000 nm wavelength range. In various embodiments, the MQLs are formed from GaAs or InGaAs-based semiconductor materials.

In various embodiments, when current flows through the active region 376 (e.g., from the first electrode 374 to the second electrode 378 or vice versa), light is generated within the active region 376. The optical cavity 360 causes amplification of the generated light such that the light may be lased along optical axis 355. In order to enable the injection of current, contact pads 372A, 372B, 372C may be disposed on a surface of the laser 350 such that contact pad 372A is in electrical communication with the first electrode 374 and the contact pads 372B, 372C are in electrical communication with the second electrode 378. Current may then be applied to the electrodes 374, 378 via the contact pads 372A, 372B, 372C to enable operation of the laser 350.

In some embodiments, the active region 376 is generally and/or substantially parallel to a plane defined by the top surface 325 of the support layer 305 such that the interfaces between the active region 376 and the first electrode 374 and between the active region 376 and the second electrode 378 are generally and/or substantially parallel to a plane defined by the top surface 325 of the support layer 305. In certain embodiments, the active region 376 is generally and/or substantially parallel to a longitudinal wall 382 of the groove 312. In such embodiments, the interfaces between the active region 376 and the first electrode 374 and between the active region 376 and the second electrode 378 are generally and/or substantially parallel to the longitudinal wall 382 of the groove 312.

In certain embodiments, one or more buffer layers 366 are disposed within the groove 312 formed in the support layer 305. For example, the buffer layer 366 is deposited along the longitudinal walls 382 of the groove 312. In various embodiments, the buffer layer 366 comprises a buffer material. The buffer material is configured to provide lattice matching between the material of the support layer 305 and the material of the second electrode 278. For example, the buffer layer 366 are configured to act as lattice strain relief layers, in certain embodiments. In some embodiments, one or more buffer layers 366 are epitaxially grown on the longitudinal walls 382 of the groove 312.

In various embodiments, the one or more buffer layers 366 are formed and/or disposed within the groove 312 such that the light emitted by the laser 350 does not pass through the buffer layer(s) 366. For example, the one or more buffer layers 366 may be formed on the longitudinal walls 382 of the groove 312 such that the one or more buffer layers 366 are not located along the optical axis 355 between the active region 376 and the etched mirror 311. Some embodiments may not include buffer layers 366 between the longitudinal walls 82 of the groove 312 and the first electrode 374, active region 376, and the second electrode 378.

In various embodiments, the optical chip 300 may include multiple support layers. For example, as described with respect to FIGS. 2A-2D, a second support layer may be bonded and/or secured to the (first) support layer 305. Etched mirrors 311 and grooves 312 may be etched into the second support layer. Active photonic components, such as lasers 350, may be formed in one or more of the grooves 312 formed in the second support layer. Additionally support layers, each having respective etched mirrors and grooves formed therein, possibly with respective lasers 350 or other active photonic components disposed within respective grooves 312, may be secured to the second support layer to provide an optical chip appropriate for the intended application.

### Example Method of Manufacturing Optical Chip with Integrated Active Photonics

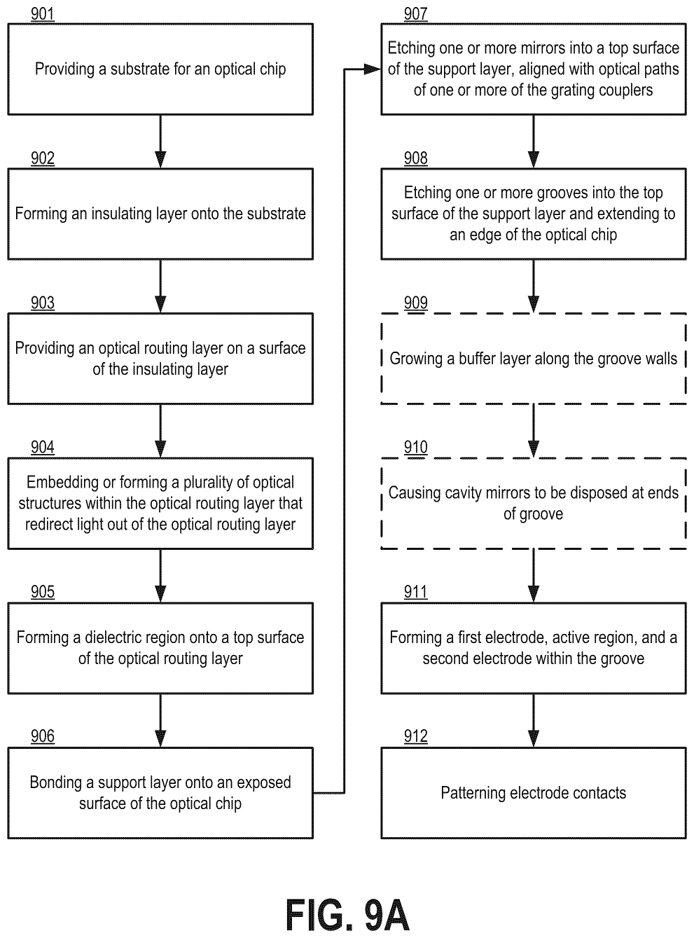

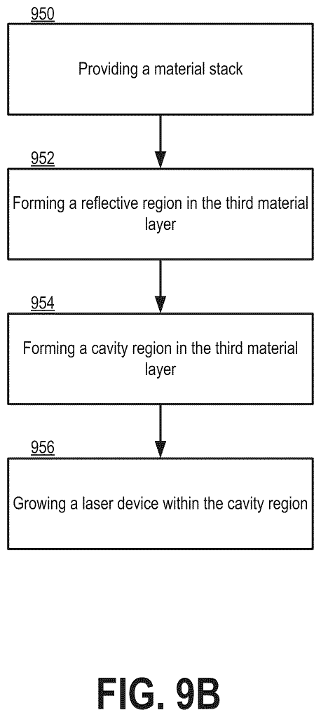

FIG. 9A illustrates an example method of manufacturing an optical chip as illustrated in FIGS. 7A-7B including an integrated laser 350 as shown in FIGS. 8A-8B.

FIG. 9A illustrates steps 901-912, which provides for one support layer including one or more etched mirrors and etched grooves therein with at least one groove having a laser 350 (or other active photonic component) disposed therein. It should be understood that an optical chip having a plurality of support layers (e.g., two or more support layers) each including one or more etched mirrors and grooves may be provided by repeating steps 906-912 of the illustrated process as many times as desired.

As shown, the method of FIG. 9A begins at step 901, where a substrate or wafer is provided for an optical chip. In an example embodiment, the substrate or wafer is a bulk silicon layer. For example, the substrate or wafer may be a standard silicon wafer, a specifically designed silicon wafer, and/or another wafer or substrate.

At step 902, an insulating layer is formed onto the substrate or wafer. For example, an insulating material layer may be deposited onto the substrate or wafer. For example, a layer of insulating material (e.g., oxide and/or the like) may be deposited onto the substrate or wafer to form an insulating layer. The insulating layer may include one or more oxide and/or insulating materials.

At step 903, an optical routing layer is bonded, deposited, patterned, and/or grown onto an exposed surface of the buried oxide layer and patterned. For example, the optical routing layer may be patterned to include one or more optical components (e.g., waveguides, guided mode optical components, and/or the like). In various embodiments, the optical routing layer is patterned to include optical components in accordance with a designed architecture appropriate for the intended application of the optical chip.

One or more optical structures, such as grating couplers 310 may be embedded, formed, and/or patterned within the optical routing layer, as shown at 904. It should be understood that other optical structures may be used in the alternative to grating couplers 310, such as forming mirrors within the optical routing layer that serve to redirect light out of the optical routing layer (e.g., upwards as illustrated in FIGS. 7A-7B). As just one alternative to embedding a grating coupler within the optical routing layer, a mirror may be etched into the top surface of the grating coupler, such as by using grayscale lithography in a manner as discussed herein with reference to other etched mirrors, that serves to redirect light directed toward the optical structure by an etched mirror into the optical routing layer (e.g., a waveguide or other guided mode component of the optical routing layer). Other components may be embedded and/or otherwise formed within the optical routing layer, as desired based on the optical chip design. For example, the optical routing layer may include various optical components such as waveguides and/or grating couplers 310.

The result of performing step 904 is similar to as shown in FIG. 3. For example, FIG. 3 illustrates a substrate 201, an insulating layer 202 formed and/or deposited onto the substrate 201, an optical routing layer 203 formed and/or patterned on the insulating layer 202, and one or more optical structures, such as grating coupler 210 embedded, formed and/or patterned within the optical routing layer 203.

Continuing with FIG. 9A, a dielectric region (comprising one or more capping layers and/or metallization layers) is provided onto the optical routing layer, as shown at step 905. For example, the dielectric region may be deposited, patterned, formed, and/or bonded onto the optical routing layer. In various embodiments, the dielectric region is fabricated in accordance with an architecture of the optical chip which is appropriate for the intended application.

A support layer is bonded onto an exposed surface of the optical chip, as shown at 906. For example, a wafer-to-wafer bonding technique may be used to bond the support layer onto the dielectric region. Where applicable, the support layer may be thinned to a desired thickness (e.g., via etching CMP, and/or the like). For example, a first support layer is bonded onto the dielectric region of the optical chip. When the optical chip is to include two or more support layers, a repetition of step 906 results in a second or additional support layer being bonded onto the exposed surface of the previous support layer

In certain embodiments, the substrate may be removed after the support layer is bonded onto the dielectric region. One or more through-vias may be formed through a surface of the insulating layer that was exposed due to removal of the substrate. The one or more through-vias may be configured to provide electrical connection and/or communication with one or more components of the dielectric region.

For example, completion of steps 901-906 may provide an optical chip 300 having a support layer bonded thereto, similar to as shown in FIG. 4. For example, FIG. 4 illustrates an optical chip 200 including an insulating layer 202, an optical routing layer 203, formed on the insulating layer 202, a grating coupler 210 formed and/or embedded in the optical routing layer 203, a dielectric region 204 provided on the optical routing layer 203, and a first support layer 205 bonded to the dielectric region 204. The substrate 201 has been removed (e.g., via etching and/or the like).

For example, in various embodiments, after bonding the first support layer 205 to the dielectric region 204, an etching is performed to remove the substrate 201. In an example embodiment, one or more through-vias providing electrical contact to components of the dielectric region 204 may be formed through the insulating layer 202 and optical routing layer 203.

After bonding of the support layer to the dielectric region, the support layer may be patterned to include one or more grooves and one or more etched mirrors that, along with the optical structures embedded in the optical routing layer, provide respective optical paths between optical components of the optical routing layer 303 and active photonic components, such as laser 350, formed and/or disposed in the grooves 312. For example, continuing with FIG. 9A, at 907, one or more etched mirrors 311 are etched into a surface 325 of the support layer 305. As discussed herein, the etched mirrors may be formed using grayscale lithography. As one example, a power intensity gradient of a lithography laser may be used to form an angled mirror sidewall surface 314 or surface within the etched cavity 315. As another example, a photoresist layer may be applied to a top surface 325 of the support layer using a gradient dosing method to adjust the depth of penetration of a lithography laser etching the etched cavity 315.

In certain embodiments, the mirror sidewall surface 314 of the etched cavity 315 may be planar or the mirrored sidewall may have a concave curvature (with a single axis of curvature or two axes of curvature). For curved mirrored sidewalls, the etching may be performed in a single step (for both forming the etched cavity 315 and forming the curvature within the mirrored sidewall surface 314) or the etching may be performed in a plurality of sequential steps (e.g., first forming a planar mirrored sidewall surface, and then forming a curvature within the mirrored sidewall surface in one or more grayscale lithography etching steps).

In certain embodiments, a metal coating is applied onto the mirror sidewall surface 314 to increase reflectivity of the mirrored sidewall surface. The metal may be gold, aluminum, silver, or other reflective metals that may be deposited in a thin-film onto the mirrored sidewall surface within the etched cavity 315 of the etched mirror 311.

The resulting mirror sidewall surface 314 is angled (and/or curved) to redirect (and/or refocus) light from a horizontal optical path portion 12 (e.g., extending horizontally along the optical axis 355 from the laser 350 to the etched mirror 311 to a vertical optical path portion 14 from the etched mirror 311 to the grating coupler 310 or other optical structure within the optical routing layer 303. It should be understood that the angle and/or focal point of the mirror sidewall surface 314 may be optimized together with the location and/or depth of the groove 312 and/or properties of the grating coupler 310 to direct light from the laser 350 disposed within the groove 312 into an optical component of the optical routing layer 303. In an example embodiment, completion of step 607 provides a material stack similar to that illustrated in FIG. 5.

Continuing at 908, one or more grooves 312 are etched into the exposed surface 325 of the support layer 305 and extending to an edge of the support layer 305 (which also defines the edge of the optical chip 300). In various embodiments, the grooves 312 are V-grooves or another appropriate groove. For example, the surface 325 of the support layer 305 may be etched to expose a <1, 1, 1> plane of the support layer 305.

Masking and wet etching, or other appropriate etching methodologies, may be utilized to form the grooves 312. The grooves 312 are aligned with the horizontal optical path portion 12 of a corresponding etched mirror 311, such that an optical axis 355 of a laser 350 disposed within the groove 312 is aligned with the horizontal optical path portion 12. For example, light emitted by the laser 350 disposed within the groove 312 will be reflected from the etched mirror 311 to travels along the vertical optical path portion 14 to the corresponding grating coupler 310 or other optical structure embedded within the optical routing layer 303.

It should be understood that the order of etching the etched mirror and the grooves may be reversed to achieve the same result. For example, in some embodiments, step 908 may be performed before step 907.

At step 909, one or more barrier layers 366 may be grown along the longitudinal walls 382 of the groove 312. In various embodiments, the one or more barrier layers 366 are configured to enable lattice matching and/or to act as lattice strain relief layers. For example, in certain embodiments, the gain material disposed in the active region 376 includes indium gallium arsenide (InGaAs) or indium gallium phosphide (InGaP), for example. In embodiments where the lattice constant of the gain material does not align with the lattice constant of the material of the support layer (e.g., silicon and/or the like), the one or more buffer layers 366 are used to provide an intermediary between the disparate lattice constants of the gain material and the support layer material. In various embodiments, the one or more buffer layers 366 are grown using an orientation-controlled epitaxial growth.

At step 910, the first cavity mirror 362 and the second cavity mirror 364 are caused to be disposed at opposite ends of the groove 312. In some embodiments, the first cavity mirror 362 and the second cavity mirror 364 may be deposited on the ends of the groove 312, grown on the ends of the groove 312, and/or pre-fabricated and installed at the ends of the groove 312.

At step 911, a first electrode 374, active region 376, and second electrode 378 are caused to be disposed within the groove 312. For example, the second electrode 378, active region 376, and first electrode 374 may be epitaxially grown within the groove 312 (e.g., between the first cavity mirror 362 and the second cavity mirror 364). For example, the second electrode 378, active region 376, and first electrode 374 may be grown within the groove 312 using orientation-controlled epitaxial growth processes. In some embodiments, the active region 376 is grown such that the active region is substantially parallel to the surface 325 of the support layer 305. In certain embodiments, the active region 376 is grown such that the active region is substantially parallel to a longitudinal wall 382 of the groove 312.

In certain embodiments, the first electrode 374, active region 376, and second electrode 378 are pre-fabricated using wafer-bonding techniques, for example, and then installed or bonded within the groove 312 (e.g., between the first cavity mirror 362 and the second cavity mirror 364).

A step 912, the contact pads 372 are deposited and patterned. For example, contact pads 372 may be deposited and fabricated such that at least one electrode contact is in electrical communication with the first electrode 374 and at least one electrode contact is in electrical communication with the second electrode 378. Depositing and pattern the contact pads 372 may include a masked deposition of an electrically conductive material and/or deposition of an electrically conductive material followed by masked and/or selective etching of the electrically conductive material.

Where more than two support layers are to be provided for the optical chip (each having etched mirrors and grooves therein), the processes of steps 906-912 may be repeated until the desired number of support layers are provided.

FIG. 9B provides a flowchart illustrating another method for fabricating an optical chip including an integrated laser device, such as optical chip 300. Starting at step 950, a material stack is provided. In various embodiments, the material stack includes a first material layer, a second material layer disposed on the second material layer, and a third material layer disposed on the second material layer. One or more optical elements are embedded in the first material layer. For example, the first material layer may be an optical routing layer 303 and/or another layer including optical elements. The optical elements may be optical components configured for routing optical signals within the first material layer (e.g., waveguides, guided mode optics, and/or the like) and/or optical structures (e.g., grating couplers 310, mirrors, and/or the like) configured to couple light into and/or out of respective optical components of the first material layer. In some embodiments, the second material layer is a dielectric region 304. In various embodiments, the third material layer is a support layer 305.

At step 952, a reflective region is formed in the third material layer. For example, the reflective region may be similar to the etched mirror 311. For example, forming the reflective region may include etching an etched mirror cavity into the third material layer, applying a reflective coating to a mirror sidewall surface of the etched mirror cavity, and/or the like, as described with respect to step 907.

At step 954, a cavity region is formed in the third material layer proximate the reflective region. For example, the cavity region may be an interior and/or opening formed in the third material layer via etching a groove into the third material layer. For example, forming a cavity region in the third material layer may include etching a groove 312 in the third material layer, as described with respect to step 908.

At step 956, following formation of the reflective region and the cavity region, a laser device is grown within the cavity region. The laser device is aligned with the reflective region such that an optical path is formed between the laser device and the optical element via the reflective region. For example, growing the laser device may include epitaxially growing a first electrode, an active region including gain material, and a second electrode within the cavity region. In certain embodiments, growing the laser device within the cavity region may include depositing one or more buffer layers along longitudinal walls that define, at least in part the cavity region, growing and/or bonding cavity mirrors at opposing ends of the cavity region (e.g., along an optical axis aligned with the reflective region), and/or patterning electrode contacts for providing electrical signals to the first electrode and the second electrode. For example, growing the laser device within the cavity region may include one or more of steps 909-912.

### Example Optical Chip with Etched Mirrors for Optical Fiber Coupling and with Integrated Active Photonics

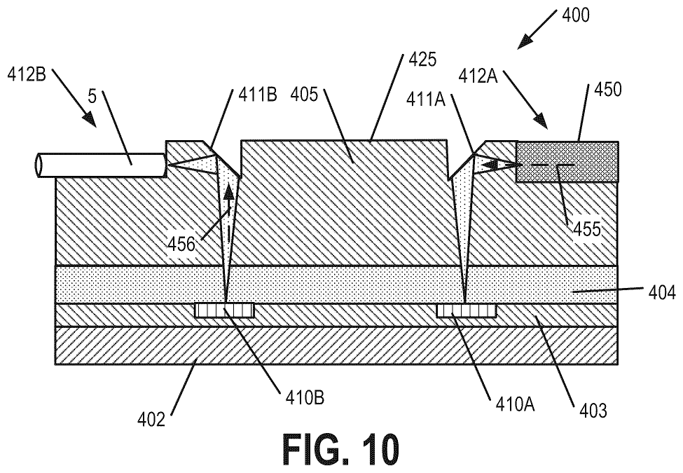

FIG. 10 provides a side cross-sectional view of an example optical chip 400 that includes both integrated active photonics, such as laser 450, that are optically coupled to an optical routing layer 403 of the optical chip 400 via etched mirrors (e.g., first etched mirror 411A) and optical fibers 5 that are optically coupled of the optical routing layer 403 via etched mirrors (e.g., second etched mirror 411B).

For example, the optical chip 400 includes an integrated laser 450 disposed within a first groove 412A. The integrated laser 450 is configured to emit light along an optical axis 455 such that the lased and/or emitted light traverses a horizontal optical path portion until the lased and/or emitted light is incident on a first etched mirror 411A. The first etched mirror 411A redirects lased and/or emitted light along a vertical optical path portion such that the lased and/or emitted light is incident on a first grating coupler 410A. The first grating coupler 410A couples the lased and/or emitted light into a first optical component of the optical routing layer 403 that corresponds to a first optical channel of the optical chip 400.

The optical chip 400 also includes a second grating coupler 410B configure to couple light out of a second optical component of the optical routing layer 403. The second optical component may be part of the first optical channel of the optical chip 400 or may be part of a second/different optical channel of the optical chip 400. The second grating coupler 140B redirects the light out of the second optical component along a corresponding vertical optical path portion (e.g., along out-coupled axis 456) such that the out-coupled light is incident on a second etched mirror 411B. The second etched mirror 411B redirects the out-coupled light along a horizontal optical path portion toward a second groove 412B. An optical fiber 5 is seated and/or secured within the second groove 412B such that the out-coupled light is coupled into the optical fiber 5 via the second etched mirror 411B and the horizontal optical path portion.

While the optical chip 400 is shown as including only one integrated laser 350 and being configured to have only one optical fiber 5 coupled thereto, it should be understood that in various embodiments, an optical chip may include a plurality of integrated lasers 450 (and/or other active photonic components) and/or be configured to have a plurality of optical fibers 5 coupled thereto, as appropriate for the application. For example, the optical chip 400 may include a plurality of optical channels, at least some of which may receive input from a respective integrated laser 450 and at least some of which may provide output to a respective optical fiber 5 coupled to the optical chip 400.

In various embodiments, the optical chip 400 includes a plurality of layers. For example, the illustrated optical chip 400 includes an insulating layer 402, an optical routing layer 403, a dielectric region 404, and a support layer 405. As should be understood, various other optical chips may include additional support layers each including respective etched mirrors and grooves for use in coupling optical fibers and/or integrating active photonic components to the optical chip 400.

As used herein, the vertical direction is a direction that is normal to a surface of a layer (e.g., the insulating layer, the optical routing layer, the dielectric layer, a support layer, and/or the like) and a horizontal direction is a direction that is within a layer (e.g., parallel to a plane defined by a surface of a layer).

The insulating layer 402 may be similar to insulating layer 302 and/or 202. In various embodiments, the insulating layer 402 provides a base structure or substrate for the optical chip 400. In an example embodiment, the insulating layer 402 is an oxide layer or buried oxide layer. For example, the insulating layer 402 may comprise a material that is electrically insulating. In an example embodiment, the insulating layer has a thickness (in the vertical direction) of 1-2 μm and comprises one or more oxide and/or insulating materials.

The optical routing layer 403 may be similar to optical routing layer 303 and/or 203. In certain embodiments, the optical routing layer 403 is configured to route or guide optical signals through respective portions of the optical chip 400. For example, the optical routing layer 403 may include various optical components, such as waveguides and/or other guided mode optical components. For example, a plurality of waveguides, guided mode optical components, and/or other active and/or passive optical components may be patterned into the optical routing layer 403. In various embodiments, the optical routing layer 403 is a top silicon layer. The optical routing layer 403 has a thickness (in the vertical direction) of about 0.5 μm, in an example embodiment. In various embodiments, the optical components of the optical routing layer 403 include silicon and/or other materials, as appropriate for the application and the optical components present.

Additionally, one or more optical structures, such as couplers (e.g., grating couplers), mirrors, and/or other optical structures may be embedded and/or formed in the optical routing layer 403. For example, the illustrated optical chip 400 includes an optical structure in the form of a first grating coupler 410A and a second grating coupler 410B. At least one of the one or more optical structures (e.g., the first grating coupler 410A) is configured to couple light propagating in a vertical direction (e.g., toward the optical routing layer 403 from the etched mirror 411 into a horizontal direction (e.g., into a layer and/or an optical component of the optical routing layer 403). At least one of the one or more optical structures (e.g., the second grating coupler 410B) is configured to couple light within the optical routing layer 403 out of the optical routing layer 403 along an out-coupled axis 456 to be coupled into an optical fiber 5, for example, via an etched mirror, such as the second etched mirror 411B.

For example, the one or more optical structures may be configured to act as Bragg reflectors couple light between respective vertical optical path portions and respective optical components of the optical routing layer 403. For example, the one or more optical structures (e.g., first grating coupler 410A) may be configured to couple light provided to the optical chip 400 via an integrated laser 450 such that the light traverses a corresponding horizontal optical path portion and traverses a corresponding vertical optical path portion into an optical component of the optical routing layer 403. In another example, the one or more optical structures (e.g., second grating coupler 410B) may be configured to couple light out of an optical component of the optical routing layer 403 such that the light traverses a corresponding vertical optical path portion and traverses a corresponding horizontal optical path portion to be coupled into an optical fiber 5 seated within a groove (e.g., second groove 412B).

The dielectric region 404 may be similar to dielectric region 304 and/or 204. In various embodiments, the dielectric region 404 includes one or more electrical components of the optical chip 400. For example, the dielectric region 404 may include capping layers and any metallization layers (not shown). In various embodiments, one or more through vias may extend through the insulating layer 402 and the optical routing layer 403 to provide electrical contact to electrical components of the dielectric region 404. For example, solder pads on the exposed surface of the insulating layer 402 may be used to place the through-vias into electrical communication with various other components of an electro-optical system including the optical chip 400.

The support layer 405 may be similar to support layer 305 and/or 205. In various embodiments, a support layer 405 is bonded to an exposed surface of the dielectric region 404. In various embodiments, a support layer 405 is a wafer, handle wafer, and/or the like. In various embodiments, a support layer 405 is a semiconductor wafer. For example, a support layer may comprise a semiconductor material such as Si, Ge, GaAs, GaN, and/or the like. For example, in some embodiments, the support layer 405 is a standard silicon wafer. For example, the support layer 405 may have a thickness of 750 μm. The support layer 405 may be thinned (e.g., using traditional wafer thinning techniques such as etching, chemical mechanical polishing (CMP), and/or the like) to a desired thickness.

The support layer 405 may be etched, patterned, and/or the like to form and/or define one or more grooves 412A, 412B and one or more etched mirrors 411A, 411B therein. The surface 425 of the support layer 405 refers to the flat planar areas on the top side (as illustrated in FIG. 10) of the wafer forming the support layer. The surface 425 is where the various layers of materials are deposited and/or where processing such as etching, doping, or photolithography occurs. The support layer 405 may be a permanent or temporary layer providing mechanical stability and that serves as a foundational layer to provide additional support to thin or delicate layers during manufacturing or processing. The support layer may be a thick, bulk layer that supports the thin layers (e.g., the optical routing layer 403, dielectric region 404, and/or the like) where the device functionality occurs.

In some embodiments, the grooves 412A, 412B are V-grooves. In various embodiments, some of the grooves (e.g., 412A) are configured for the formation active photonic components (e.g., integrated lasers and/or the like) therein. This allows for the lateral scalability of lasers and their respective optical cavities, for example, while providing integration of optical sources in optical chips.

The exposed surface 425 of the support layer 405 may be etched as shown in FIG. 10 to form etched mirrors 411A, 411B and/or grooves 412A, 412B. In various embodiments, the etched mirrors 411A, 411B may be fabricated in a similar manner as etched mirrors 311 and/or 211. For example, the etched mirrors 411A, 411B may each include a reflective surface (e.g., mirror sidewall surface formed within an etched cavity in the exposed surface 425 of a support layer). The etched mirror 411A, 411B may be formed using a technique similar to that described with respect to etched mirrors 311, 211. For example, to form the etched mirror 411A, 411B, a cavity may be etched into the exposed surface 425 of the support layer 405 using grayscale lithography. For example, the etched mirrors 411A, 411B may be planar mirrors or curved mirrors (in one-or two-dimensions) and may include a reflective coating.

As shown in FIG. 10, each etched mirror 411A, 411B is aligned with a corresponding optical structure, such as the grating couplers 410A, 410B, in the optical routing layer 403. The illustrated grating couplers 410A, 410B act as Bragg reflectors configured to redirect light, such as redirecting light received by the grating coupler along a corresponding vertical optical path portion into the optical routing layer 403 or redirecting light out of the optical routing layer 403 and along a corresponding vertical optical path portion.

The grating coupler 410A, 410B (or other optical structure configured to couple light into/out of the optical routing layer 403) and the corresponding etched mirror 411A, 411B may be co-optimized to enable the correct optical mode diameter and reflective properties needed for a desired implementation. For example, in various embodiments, the etched mirror 411A, 411B and/or the grating coupler 410A, 410B (or other optical structure embedded in the optical routing layer 403) are configured to cause an optical beam that traverses an optical path defined, at least in part, by the etched mirror 411A, 411B and the grating coupler 410A, 410B and the etched mirror to have, when the light is coupled into the optical routing layer 403 and/or into an optical fiber 5, an optical mode diameter that matches the mode field diameter of an optical component (e.g., waveguide, guided mode optical component, and/or other optical component) of the optical routing layer 303 or of the optical fiber 5.

As shown in FIG. 10, grooves 412A, 412B is etched into the exposed surface 425 of the support layer 405, for example, using wet etching techniques. In an example embodiment, the grooves 412A, 412B are V-grooves. For example, the top surface 425 of the support layer 405 may be a <1,0,0> plane of the material of the support layer 405 and grooves 412A, 412B may be etched to expose respective <1,1,1> planes of the material of the support layer 405. The grooves 412A, 412B may be etched by applying a masking layer onto the exposed surface of the support layer 405, with a gap in the masking corresponding to the size and location of the groove. For example, the grooves 412A, 412B may be etched in similar manner as the grooves 312, 212. In certain embodiments, the distance between respective grooves 412A, 412B and the corresponding etched mirrors 411A, 411B and/or depth of the grooves 412A, 412B may differ to enable positioning a plurality of paths at various locations of the optical chip 400 and/or to prevent overlapping of optical paths of the optical chip 400.

In various embodiments, one or more active photonic components may be formed and/or disposed within respective grooves (e.g., the first groove 412A) of the optical chip 400. For example, a laser 450 is formed and/or disposed within the first groove 412A. The laser 450 may be similar to laser 350. For example, the laser 450 includes a first electrode, an active region, and a second electrode, where the active region includes gain material and is disposed between the first electrode and the second electrode. The laser 450 may further include at least two contact pads (e.g., at least one contact pad in communication with each of the first electrode and the second electrode). The laser 450 may further include a first cavity mirror and a second cavity mirror configured to define an optical cavity with the gain material of the active region disposed within the optical cavity. In certain embodiments, the laser 450 may also include one or more buffer layers that provide for lattice matching and/or lattice strain relief between the support layer and the electrodes and/or active region of the laser 450.

In various embodiments, one or more optical fibers 5 are optically and mechanically coupled to the optical chip 400 via respective grooves etched and/or formed into the support layer 405. For example, an optical fiber 5 is seated within the second groove 412B, such that light traveling along the illustrated optical path (including vertical optical path portion between the second grating coupler 410B and the second etched mirror 411B and horizontal optical path portion between the second etched mirror 411B and the second groove 412B) would be provided from the second grating coupler 410B, reflected off of the second etched mirror 411B to an in-plane direction that is at least substantially parallel with the exposed surface 425 of the support layer 405 and directed into the second groove 412B, where it would pass into the optical fiber 5 mechanically mounted within the second groove 412B. For example, the second groove 412B, second etched mirror 411B, and second grating coupler 410B (or another optical structure) define an optical path (consisting of a horizontal optical path portion and the vertical optical path portion) that place an optical component (e.g., waveguide, guided mode optical component, and/or other optical component) of the optical routing layer 403 into optical communication with an optical fiber 5 seated within the second groove 412B.

In various embodiments, the optical chip 400 may include multiple support layers. For example, as described with respect to FIGS. 2A-2D, a second support layer may be bonded and/or secured to the (first) support layer 405. Etched mirrors 411 and grooves 412 may be etched into the second support layer. Active photonic components, such as lasers 450, may be formed in one or more of the grooves 412 formed in the second support layer. Optical fibers 5 may be optically and mechanically coupled to the optical chip 400 via one or more of the grooves 412 formed in the second support layer. Additionally support layers, each having respective etched mirrors and grooves formed therein, possibly with respective lasers 450 or other active photonic components disposed within respective grooves 412 and/or optical fibers 5 seated within respective grooves 412, may be secured to the second support layer to provide an optical chip appropriate for the intended application.

### Example Method of Manufacturing Optical Chip with Etched Mirrors for Optical Fiber Coupling and Integrated Active Photonics

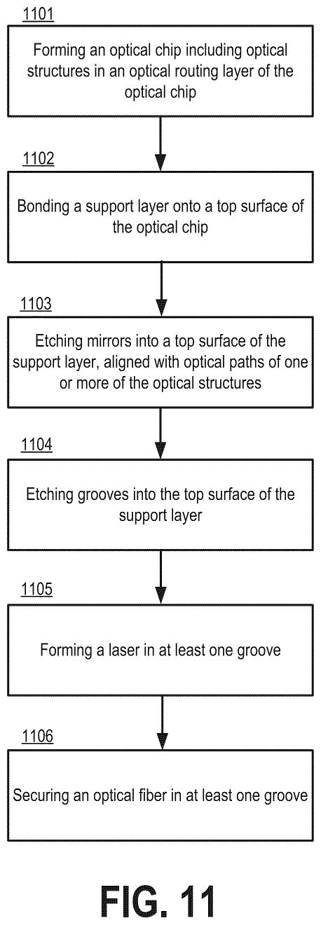

FIG. 11 illustrates an example method of manufacturing an optical chip as illustrated in FIG. 10 including etched mirrors for optical fiber coupling and for coupling integrated active photonics, such as an integrated laser 450.

FIG. 11 illustrates steps 1101-1106, which provides for one support layer including one or more etched mirrors and etched grooves therein with at least one groove having a laser 450 (or other active photonic component) disposed therein and at least one groove having an optical fiber 5 seated therein. It should be understood that an optical chip having a plurality of support layers (e.g., two or more support layers) each including one or more etched mirrors and grooves may be provided by repeating steps 1102-1105 of the illustrated process as many times as desired.

As shown, the method of FIG. 11 begins at step 1101, where an optical chip including an optical routing layer having optical structures embedded therein is fabricated. For example, the optical chip may be fabricated to include an insulating layer, an optical routing layer, and a dielectric region. The optical structures embedded in the optical routing layer may be include grating couplers, mirrors, and/or the like. For example, step 1101 may be performed by performing steps 601-605 of FIGS. 6 and/or steps 901-905 of FIG. 9A.

A support layer is bonded onto an exposed surface of the optical chip, as shown at 1102. For example, a wafer-to-wafer bonding technique may be used to bond the support layer onto the dielectric region. Where applicable, the support layer may be thinned to a desired thickness (e.g., via etching CMP, and/or the like). For example, a first support layer is bonded onto the dielectric region of the optical chip. When the optical chip is to include two or more support layers, a repetition of step 1102 results in a second or additional support layer being bonded onto the exposed surface of the previous support layer

In certain embodiments, the substrate may be removed after the support layer is bonded onto the dielectric region. One or more through-vias may be formed through a surface of the insulating layer that was exposed due to removal of the substrate. The one or more through-vias may be configured to provide electrical connection and/or communication with one or more components of the dielectric region.

After bonding of the support layer to the dielectric region, the support layer may be patterned to include one or more grooves and one or more etched mirrors that, along with the optical structures embedded in the optical routing layer, provide respective optical paths between optical components of the optical routing layer 403 and active photonic components, such as laser 450, formed and/or disposed in the grooves 412 and/or optical fibers 5 seated in grooves 412. For example, continuing with FIG. 11, at 1103, one or more etched mirrors 411 are etched into a surface 425 of the support layer 405. As discussed herein, the etched mirrors may be formed using grayscale lithography. As one example, a power intensity gradient of a lithography laser may be used to form an angled mirror sidewall surface or surface within the etched mirror cavity. As another example, a photoresist layer may be applied to a top surface 425 of the support layer using a gradient dosing method to adjust the depth of penetration of a lithography laser etching the etched mirror cavity.

In certain embodiments, the mirror sidewall surface of the etched mirror cavity may be planar or the mirrored sidewall may have a concave curvature (with a single axis of curvature or two axes of curvature). For curved mirrored sidewalls, the etching may be performed in a single step (for both forming the cavity and forming the curvature within the mirrored sidewall surface) or the etching may be performed in a plurality of sequential steps (e.g., first forming a planar mirrored sidewall surface, and then forming a curvature within the mirrored sidewall surface in one or more grayscale lithography etching steps).

In certain embodiments, a metal coating is applied onto the mirror sidewall surface to increase reflectivity of the mirrored sidewall surface. The metal may be gold, aluminum, silver, or other reflective metals that may be deposited in a thin-film onto the mirrored sidewall surface within the etched cavity of the etched mirror 411.

The resulting mirror sidewall surface is angled (and/or curved) to redirect (and/or refocus) light from a horizontal optical path portion to a vertical optical path portion aligned with to the grating coupler 410 or other optical structure within the optical routing layer 403 (or vice versa such that the optical path optically couples the grating coupler 410 and the corresponding groove 412). It should be understood that the angle and/or focal point of the mirror sidewall surface may be optimized together with the location and/or depth of the groove 412 and/or properties of the grating coupler 410 to direct light from the laser 450 disposed within the groove 412 into an optical component of the optical routing layer 403 and/or to direct light from an optical component of the optical routing layer 403 to an optical fiber 5 seated in the groove 412. In an example embodiment, completion of step 1103 provides a material stack similar to that illustrated in FIG. 5.

Continuing at 1104, one or more grooves 412 are etched into the exposed surface 425 of the support layer 405 and extending to an edge of the support layer 405 (which also defines the edge of the optical chip 400). The edge of the support layer 405 is the outer perimeter or boundary of the wafer/support layer 405. The edge typically includes the rounded or beveled part of the wafer that transitions between the top surface 425 and bottom surface (as illustrated in FIG. 10) of the support layer 405. In various embodiments, the grooves 412 are V-grooves or another appropriate groove. For example, the surface 425 of the support layer 405 may be etched to expose a <1, 1, 1> plane of the support layer 405.

Masking and wet etching, or other appropriate etching methodologies, may be utilized to form the grooves 412. The grooves 412 are aligned with the horizonal optical path portion of a corresponding etched mirror 411, such that an optical axis 455 of a laser 450 disposed within the groove 412 is aligned with the horizontal optical path portion and/or such that a core of an optical fiber 5 seated within the groove is aligned with the horizontal optical path portion. For example, light emitted by the laser 450 disposed within the first groove 412A will be reflected from the first etched mirror 411A to travel along the vertical optical path portion to the first grating coupler 410A or other optical structure embedded within the optical routing layer 403. For example, light coupled out of the optical routing layer 403 via a second grating coupler 410B will be reflected from the second etched mirror 411B to travel along a horizontal optical path portion to the second groove 412B to be coupled into the optical fiber 5 seated therein.

It should be understood that the order of etching the etched mirror and the grooves may be reversed to achieve the same result. For example, in some embodiments, step 1103 may be performed before step 1104.

At step 1105, a laser 450 (or other active photonic component) is formed within at least one of the grooves 412 etched at step 1104. For example, the laser 450 is fabricated within the first groove 412A. For example, in certain embodiments, one or more buffer layers that provide for lattice matching and/or lattice strain relief between the support layer and the electrodes and/or active region of the laser 450 may be formed within the first groove 412A. A first cavity mirror and a second cavity mirror configured to define an optical cavity with the gain material of the active region disposed within the optical cavity may be formed at the longitudinal ends of the first groove 412A. A first electrode, an active region, and a second electrode, where the active region includes gain material and is disposed between the first electrode and the second electrode may be formed within the first groove 412A. In various embodiments, the first electrode, active region, and second electrode may be epitaxially grown within the first groove 412A. In another example embodiment, the first electrode, active region, and second electrode may be pre-fabricated (e.g., using wafer-bonding and/or the like) and then bonded into the first groove 412A. At least two contact pads (e.g., at least one contact pad in communication with each of the first electrode and the second electrode) may be deposited and patterned into electrical communication with respective electrodes of the laser 450. For example, steps 909-912 may be performed to form at least one laser (or other active photonic component) within at least one of the grooves formed and/or etched into the surface 425 of the support layer 405.

Where more than two support layers are to be provided for the optical chip (each having etched mirrors and grooves therein), the processes of steps 1102-1105 may be repeated until the desired number of support layers are provided. As shown at 1106, at least one optical fiber is coupled into at least one groove formed in the preceding steps. For example, optical fiber 5 is coupled into the second groove 412B. It should be understood that the optical fibers may be coupled at any point after formation of the grooves. For example, the optical fibers may be mechanically secured into the grooves 412. For example, completion of steps 1106 may provide an optical chip as illustrated in FIG. 10.

### Example Datacenter

In various embodiments, an optical chip 200 may be part of a datacenter. For example, an optical chip 200 may be used to place various components of a datacenter in communication with one another. For example, an optical chip 200 may be used to (optically) transmit data between components of a datacenter, in various embodiments. For example, an optical communication path between two components of a datacenter may include an optical chip 200, in accordance with an example embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gb/s. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

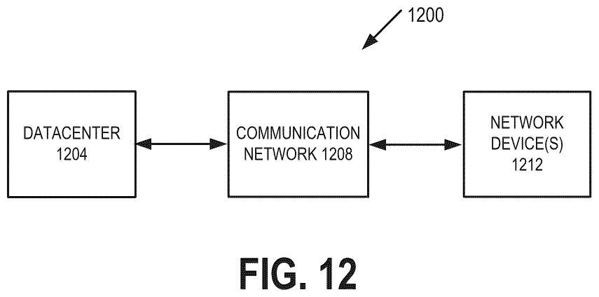

FIG. 12 illustrates a system 1200 according to at least one example embodiment. The system 1200 includes a datacenter 1204, a communication network 1208, and one or more network devices 1212. In at least one example embodiment, the datacenter 1204 corresponds to a collection of network devices, such as network switches (e.g., Ethernet switches) connected with a collection of servers or compute nodes. The datacenter 1204 may adhere to a networking topology (e.g., a hierarchal networking topology), such as a fat tree topology, a Slim Fly topology, a Dragonfly topology, and/or the like. The datacenter 1204 routes traffic amongst the network switches and servers therein, and at least one layer of the topology in the datacenter 1204 is coupled to the communication network 1208 to allow networking traffic to flow between the datacenter 1204 and the network device(s) 1212.

Examples of the communication network 1208 that may be used to connect the datacenter 1204 and the network device(s) 1212 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 1212 may include one or more of Personal Computer (PC), a laptop, a tablet, a smartphone, a server, a collection of servers, and/or any suitable computing device for sending and receiving signals over the communication network 1208. In at least one example embodiment, the one or more network devices 1212 correspond to another datacenter, similar to or the same as datacenter 1204.

As noted above, the datacenter 1204 and/or the network device(s) 1212 may include storage devices and/or processing circuitry for carrying out computing tasks, for example, tasks associated with controlling the flow of data internally and/or over the communication network 1208. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry may comprise hardware, such as an application specific integrated circuit (ASIC). Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 1204 and network device(s) 1212 may include one or more communication interfaces for facilitating wired and/or wireless communication between one another and other unillustrated elements of the system 1200.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

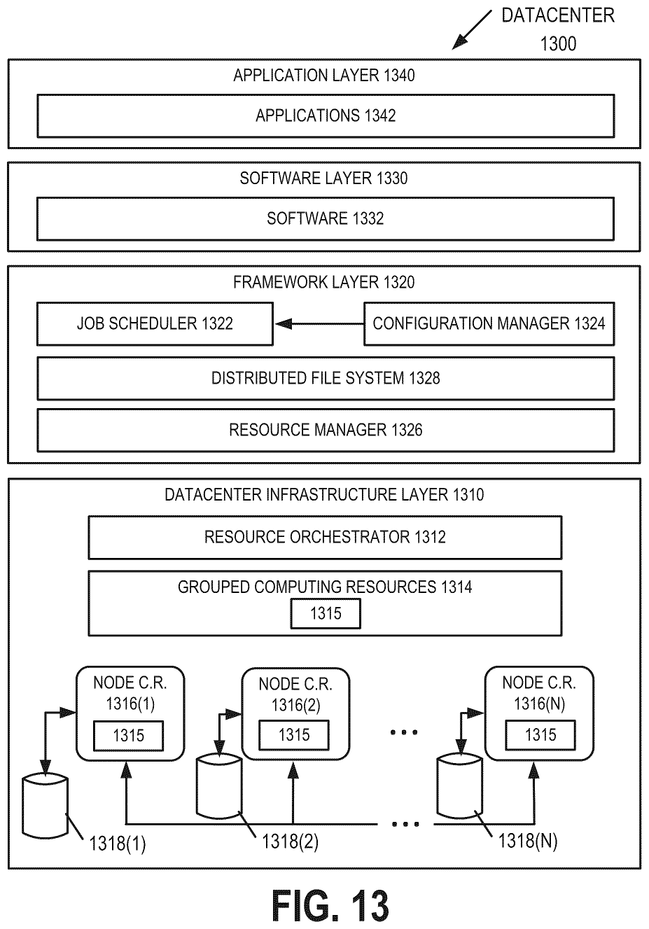

FIG. 13 illustrates an example datacenter 1300, in which at least one embodiment may be used. In at least one embodiment, datacenter 1300 includes a datacenter infrastructure layer 1310, a framework layer 1320, a software layer 1330, and an application layer 1340.

In at least one embodiment, as shown in FIG. 13, datacenter infrastructure layer 1310 may include a resource orchestrator 1312, grouped computing resources 1314, and node computing resources (“node C.R.s”) 1316(1)-1316(N), where “N” represents a positive integer (which may be a different integer “N” than used in other figures). In at least one embodiment, node C.R.s 1316(1)-1316(N) may include, but are not limited to, any number of central processing units (“CPUs”) or other processors (including accelerators, field programmable gate arrays (FPGAs), graphics processors, etc.), memory storage devices 1318(1)-1318(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 1316(1)-1316(N) may be a server having one or more of above-mentioned computing resources.

In at least one embodiment, grouped computing resources 1314 may include separate groupings of node C.R.s housed within one or more racks (not shown), or many racks housed in datacenters at various geographical locations (also not shown). In at least one embodiment, separate groupings of node C.R.s within grouped computing resources 1314 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1312 may configure or otherwise control one or more node C.R.s 1316(1)-1316(N) and/or grouped computing resources 1314. In at least one embodiment, resource orchestrator 1312 may include a software design infrastructure (“SDI”) management entity for datacenter 1300. In at least one embodiment, resource orchestrator 1312 may include hardware, software or some combination thereof.

In at least one embodiment, as shown in FIG. 13, framework layer 1320 includes a job scheduler 1322, a configuration manager 1324, a resource manager 1326 and a distributed file system 1328. In at least one embodiment, framework layer 1320 may include a framework to support software 1332 of software layer 1330 and/or one or more application(s) 1342 of application layer 1340. In at least one embodiment, software 1332 or application(s) 1342 may respectively include web-based service software or applications, such as those provided by Amazon Web Services, Google Cloud and Microsoft Azure. In at least one embodiment, framework layer 1320 may be, but is not limited to, a type of free and open-source software web application framework such as Apache Spark™ (hereinafter “Spark”) that may utilize distributed file system 1328 for large-scale data processing (e.g., “big data”). In at least one embodiment, job scheduler 1322 may include a Spark driver to facilitate scheduling of workloads supported by various layers of datacenter 1300. In at least one embodiment, configuration manager 1324 may be capable of configuring different layers such as software layer 1330 and framework layer 1320 including Spark and distributed file system 1328 for supporting large-scale data processing. In at least one embodiment, resource manager 1326 may be capable of managing clustered or grouped computing resources mapped to or allocated for support of distributed file system 1328 and job scheduler 1322. In at least one embodiment, clustered or grouped computing resources may include grouped computing resources 1314 at datacenter infrastructure layer 1310. In at least one embodiment, resource manager 1326 may coordinate with resource orchestrator 1312 to manage these mapped or allocated computing resources.

In at least one embodiment, software 1332 included in software layer 1330 may include software used by at least portions of node C.R.s 1316(1)-1316(N), grouped computing resources 1314, and/or distributed file system 1328 of framework layer 1320. In at least one embodiment, one or more types of software may include, but are not limited to, Internet web page search software, e-mail virus scan software, database software, and streaming video content software.

In at least one embodiment, application(s) 1342 included in application layer 1340 may include one or more types of applications used by at least portions of node C.R.s 1316(1)-1316(N), grouped computing resources 1314, and/or distributed file system 1328 of framework layer 1320. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1324, resource manager 1326, and resource orchestrator 1312 may implement any number and type of self-modifying actions based on any amount and type of data acquired in any technically feasible fashion. In at least one embodiment, self-modifying actions may relieve a datacenter operator of datacenter 1300 from making possibly bad configuration decisions and possibly avoiding underutilized and/or poor performing portions of a datacenter.

In at least one embodiment, datacenter 1300 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 1300. In at least one embodiment, trained machine learning models corresponding to one or more neural networks may be used to infer or predict information using resources described above with respect to datacenter 1300 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1315 are used to perform inferencing and/or training operations associated with one or more embodiments. In at least one embodiment, inference and/or training logic 1315 may be used in system FIG. 13 for inferencing or predicting operations based, at least in part, on weight parameters calculated using neural network training operations, neural network functions and/or architectures, or neural network use cases described herein.

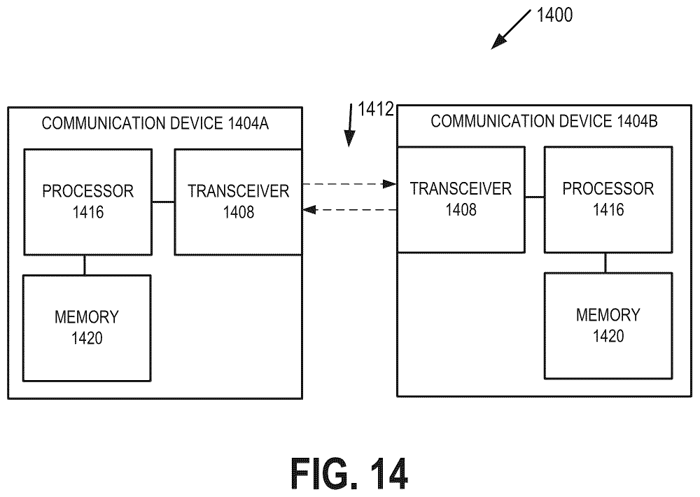

FIG. 14 illustrates a system 1400 including a first communication device 1404A and a second communication device 1404B. Illustratively, but without limitation, the communication devices 1404 (e.g., 1404A, 1404B) may correspond to network devices (e.g., network devices 1212). As such, the communication devices 1404 may correspond to any type of device that becomes part of or is connected with a communication network (e.g., communication network 1208). Examples of suitable devices that may act or operate like a communication device 1404 as described herein include, without limitation, one or more of a Personal Computer (PC), a laptop, a tablet, a smartphone, a server, a collection of servers, a networking card, an edge router, a switch, Network Interface Cards, a Top of Rack (ToR) switch, a server blade, or the like. The communication device 1404 may include a transceiver 1408, a processor 1416, and memory 1420. The transceiver 1408 may include hardware that enables communications over the communication channel 1412 whereas the processor 1416 and memory 1420 may include components that enable the communication device 1404 to provide a desired functionality or perform certain functions.

The communication channel 1412 may traverse a datacenter or any type of communication network (whether trusted or untrusted). Examples of a communication network that may be used to connect communication devices 1404 and support the communication channel 1412 include, without limitation, an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network enables data transmission between the communication devices 1404 using optical signals. In this case, the communication devices 1404 and the communication network may include waveguides (e.g., optical fibers) that carry the optical signals. For example, the communication devices and/or the communication network may include one or more optical chips 200, 300, 400, according to various embodiments.

### CONCLUSION

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. An optical chip, comprising:
a plurality of optical structures embedded within an optical routing layer;
a first support layer secured with respect to the optical routing layer, wherein the first support layer has a first etched mirror and a first groove on an edge of the first support layer aligned with the first etched mirror formed in an exposed surface of the first support layer; and
a second support layer, bonded onto the exposed surface of the first support layer, wherein the second support layer has a second etched mirror and a second groove on an edge of the second support layer aligned with the second etched mirror formed in an exposed surface of the second support layer,
wherein the first etched mirror and the second etched mirror are optically aligned with a first optical structure and a second optical structure of the plurality of optical structures, respectively.

2. The optical chip of claim 1, wherein the first optical structure and the second optical structure are grating couplers that are laterally aligned within the optical routing layer.

3. The optical chip of claim 2, wherein the first groove and the second groove are vertically aligned.

4. The optical chip of claim 3, wherein the first etched mirror and the second etched mirror are out of alignment with one another.

5. The optical chip of claim 4, wherein the first etched mirror is a first concave mirror having a first focal length, and the second etched mirror is a second concave mirror having a second focal length, wherein the first focal length is different from the second focal length.

6. The optical chip of claim 1, further comprising at least a third groove in the first support layer and a fourth groove in the second support layer, wherein the first groove, the second groove, the third groove, and the fourth groove collectively define a two-dimensional array of grooves.

7. The optical chip of claim 1, wherein the first groove is on a first edge of the first support layer and the second groove is on a second edge of the second support layer; wherein the first edge of the first support layer is perpendicular to the second edge of the second support layer.

8. The optical chip of claim 1, wherein the first etched mirror and the second etched mirror are angled mirror surfaces formed within the first support layer and the second support layer, respectively, to redirect an optical path from respective optical structures to the first groove and the second groove, respectively.

9. A method for fabricating an optical chip, comprising:
forming a dielectric region onto an exposed surface of an optical routing layer of the optical chip, wherein the optical routing layer has a plurality of optical structures embedded therein;
securing a first support layer onto an exposed surface of the dielectric region;
etching at least a first etched mirror and a first groove into an exposed surface of the first support layer, wherein the first etched mirror is positioned to redirect a first optical path from a first optical structure of the plurality of optical structures into the first groove and the first groove extends to an edge of the first support layer;
bonding a second support layer onto the exposed surface of the first support layer; and
etching at least a second etched mirror and a second groove into an exposed surface of the second support layer, wherein the second etched mirror is positioned to redirect a second optical path from a second optical structure of the plurality of optical structures and into the second groove and the second groove extends to an edge of the second support layer.

10. The method of claim 9, further comprising:
coupling a first optical fiber at least partially positioned within the first groove; and
coupling a second optical fiber at least partially positioned within the second groove.

11. The method of claim 9, further comprising:
etching at least a third etched mirror and a third groove into an exposed surface of the first support layer; and
etching at least a fourth etched mirror and a fourth groove into an exposed surface of the second support layer.

12. The method of claim 11, wherein each of the first groove, the second groove, the third groove, and the fourth groove extend through a first edge of the optical chip.

13. The method of claim 9, wherein the optical routing layer is disposed on an insulating layer formed on a substrate, and the method further comprises removing the substrate.

14. The method of claim 13, further comprising forming through-vias within the insulating layer.

15. The method of claim 9, wherein the plurality of optical structures comprise at least one of a grating coupler or a mirror.

16. The method of claim 9, wherein bonding the second support layer onto the exposed surface of the first support layer comprises wafer-to-wafer bonding.

17. The method of claim 9, wherein etching the first etched mirror and etching the second etched mirror comprises grayscale lithography etching.

18. The method of claim 17, wherein etching the first etched mirror comprises at least two grayscale lithography etching steps.

19. The method of claim 9, further comprising depositing a metal coating onto the first etched mirror and depositing a metal coating onto the second etched mirror.

20. A method comprising:
etching at least a first etched mirror and a first groove into an exposed surface of a first support layer, wherein the first etched mirror and the first groove define a first portion of a first optical path;
bonding a second support layer onto the exposed surface of the first support layer,
etching at least a second etched mirror and a second groove into an exposed surface of the second support layer, wherein the second etched mirror and the second groove define a first portion of a second optical path, wherein the second optical path and the first optical path do not intersect one another.

21. An optical interconnect for coupling a plurality of optical fibers to an optical chip, the optical interconnect comprising:
two or more support layers bonded to one another, each support layer of the two or more support layers comprising at least one etched mirror and at least one groove configured to receive an optical fiber of the plurality of optical fibers therein, the at least one etched mirror is configured to at least partially define an optical path between the at least one groove and a corresponding optical structure embedded in an optical routing layer of the optical chip,
wherein at least one of the at least one etched mirror or the corresponding optical structure is configured to cause an optical beam that traversed the optical path to have, within at least a portion of the groove, an optical mode diameter that matches a mode field diameter of the optical fiber.
